(19) United States
(12) Patent Application Publication
(10) Pub. No.: US 2026/0349344 A1
(43) Pub. Date: Nov. 5, 2026

(54) PATTERNING PROCESS

(71) Applicant: SHIN-ETSU CHEMICAL CO., LTD., Tokyo (JP)

(72) Inventors: Satoshi KUSAMA, Joetsu-shi (JP); Tsunehiro NISHI, Joetsu-shi (JP); Masaki OHASHI, Joetsu-shi (JP)

(73) Assignee: SHIN-ETSU CHEMICAL CO., LTD., Tokyo (JP)

(21) Appl. No.: 19/651,196

(22) Filed: Apr. 17, 2026

(30) Foreign Application Priority Data
Apr. 22, 2025 (JP) 2025-070790

(51) Int. Cl. G03F 7/075; G03F 7/16; G03F 7/20

(52) U.S. Cl. CPC G03F 7/0757; G03F 7/167; G03F 7/2004

(57) ABSTRACT

The object of the present invention is to provide a patterning process that is excellent in sensitivity, resolution, and LWR in photolithography using BEUV. A patterning process including the steps of: (1) forming a resist film on a substrate or on an underlayer film stacked on a substrate; (2) exposing the resist film to BEUV light having a wavelength of 2 to 10 nm; and (3) developing the exposed resist film to form a resist pattern, in which the resist film contains a silsesquioxane compound.

### TECHNICAL FIELD

The present invention relates to a patterning process.

### BACKGROUND ART

As the IoT market expands, demand for higher integration, higher speeds, and lower power consumption in LSIs is growing, leading to rapid progress in miniaturization of pattern rules. Logic devices, in particular, are driving this miniaturization. The most advanced miniaturization technologies are ArF immersion lithography, with double patterning, triple patterning, and quadruple patterning, leading to mass production of 10 nm-node devices, and research is also underway to develop 7 nm-node devices using next-generation extreme ultraviolet (EUV) lithography having a wavelength of 13.5 nm.

Development of beyond EUV (BEUV) lithography, having a wavelength of 2 to 10 nm, is underway as a next-generation exposure technology (Non-Patent Document 1). Using a light source with a short wavelength is expected to improve lithography resolution performance and achieve further miniaturization. However, BEUV is a high-energy light beam, and thus the number of photons per unit energy is lower than EUV light sources, resulting in the problem of low sensitivity in lithography.

As miniaturization progresses, image blurring due to acid diffusion has become a problem (Non-Patent Document 2). In order to ensure resolution in fine patterns in generations with a processing dimension of 45 nm and beyond, it has been suggested that controlling acid diffusion is important, in addition to improving dissolution contrast, as has been proposed previously (Non-Patent Document 2). However, chemically amplified resist compositions increase sensitivity and contrast through acid diffusion, and thus attempts to minimize acid diffusion by lowering the post-exposure bake (PEB) temperature or shortening the PEB time result in significant decreases in sensitivity and contrast.

Suppressing acid diffusion by adding an acid generator that generates bulky acid is effective. Thus, it has been proposed to copolymerize, with a polymer, an onium salt acid generator having a polymerizable olefin. However, for resist film patterning in generations with a processing dimension of 16 nm and beyond, it is considered that chemically amplified resist compositions will not be able to form patterns due to acid diffusion, leading to a need for the development of non-chemically amplified resist compositions.

Examples of a material for non-chemically amplified resist compositions include polymethyl methacrylate (PMMA). PMMA is a positive resist material in which the main chain is cut by electron beam (EB) or EUV irradiation, reducing its molecular weight and improving its solubility in organic solvent developers, but having no ring structure causes drawbacks such as low etching resistance and large amounts of outgassing during exposure.

Hydrogen silsesquioxane (HSQ) is a material for negative resist compositions in which EB or EUV irradiation generates silanols and the condensation reaction of the silanols causes crosslinking, leading to insolubility in alkaline developers (Non-Patent Document 3). This material has a small molecular size before crosslinking and is free of blurring due to acid diffusion, resulting in low edge roughness and extremely high resolution, and thus is used as a pattern transfer material for indicating the resolution limit of exposure apparatuses. However, silicon, the main constituent component of HSQ, is problematic in that it has a small molar absorption coefficient at 13.5 nm, and thus resists composed of HSQ fail to effectively capture the energy of EUV light, resulting in low sensitivity in lithography.

### CITATION LIST

### Non Patent Literature

Non-patent Document 1: SPIE Vol. 8322 p 1 (2012)
Non-patent Document 2: SPIE Vol. 5039 p 1 (2003)
Non-patent Document 3: Nanotechnology Vol. 20 p 292001 (2009)

### SUMMARY OF INVENTION

### Technical Problem

The present invention has been developed in consideration of the above circumstances, and an object thereof is to provide a patterning process that is excellent in sensitivity, resolution, and LWR in photolithography using BEUV.

### Solution to Problem

In order to solve the above problems, the present invention provides a patterning process comprising the steps of:
(1) forming a resist film on a substrate or on an underlayer film stacked on a substrate;
(2) exposing the resist film to BEUV light having a wavelength of 2 to 10 nm; and
(3) developing the exposed resist film to form a resist pattern,
   wherein the resist film contains a silsesquioxane compound.

The patterning process of the present invention exhibits excellent sensitivity, resolution, and LWR in photolithography using BEUV.

In addition, in the step (1), the resist film can be formed by CVD or ALD.

Alternatively, in the step (1), the resist film can be formed by applying a resist composition.

In the present invention, a resist film can be formed in this manner.

In this case, the resist composition can include a fully caged silsesquioxane compound represented by the following formula (1):

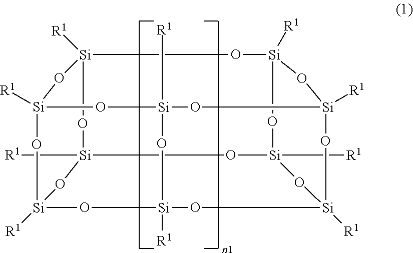

wherein “n1” is an integer of 0 to 40, R¹ is a hydrogen atom, a hydrocarbyl carbonyl group having 1 to 40 carbon atoms and optionally including a heteroatom, or a hydrocarbyl group having 1 to 40 carbon atoms and optionally including a heteroatom, and each R¹ is the same as or different from each other.

Alternatively, the resist composition may include a partially caged silsesquioxane compound represented by the following formula (2):

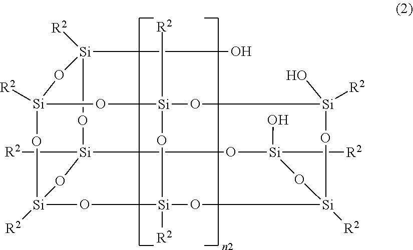

wherein “n2” is an integer of 0 to 40, R² is a hydrogen atom, a hydrocarbyl carbonyl group having 1 to 40 carbon atoms and optionally including a heteroatom, or a hydrocarbyl group having 1 to 40 carbon atoms and optionally including a heteroatom, and each R² is the same as or different from each other.

Alternatively, the resist composition may include a ladder-type silsesquioxane compound represented by the following formula (3):

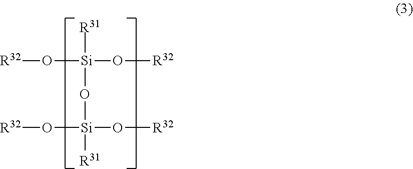

wherein R³¹ is a hydrogen atom, a hydrocarbyl carbonyl group having 1 to 40 carbon atoms and optionally including a heteroatom, or a hydrocarbyl group having 1 to 40 carbon atoms and optionally including a heteroatom, each R³¹ is the same as or different from each other, R³² is a hydrogen atom, a hydrocarbyl carbonyl group having 1 to 40 carbon atoms and optionally including a heteroatom, or a hydrocarbyl group having 1 to 40 carbon atoms and optionally including a heteroatom, each R³² is the same as or different from each other, and [ ] indicates a repeating unit.

Alternatively, the resist composition may include a silsesquioxane resin having a repeating unit represented by the following formula (4a) or (4b):

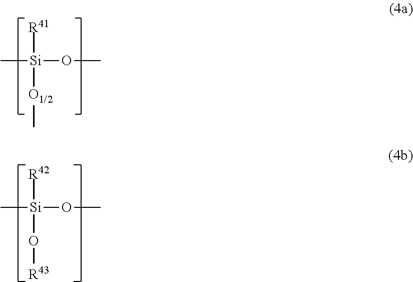

wherein R⁴¹, R⁴², and R⁴³ are each independently a hydrogen atom, a hydrocarbyl carbonyl group having 1 to 40 carbon atoms and optionally including a heteroatom, or a hydrocarbyl group having 1 to 40 carbon atoms and optionally including a heteroatom.

Alternatively, the resist composition may include a polymer having a repeating unit represented by the following formula (5):

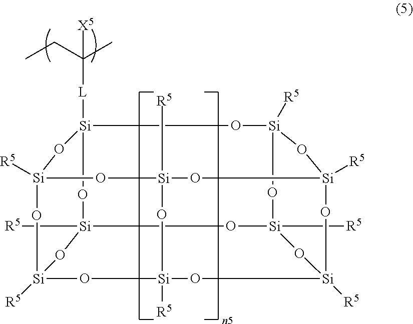

wherein “n5” is an integer of 0 to 40, R⁵ is a hydrogen atom, a hydrocarbyl carbonyl group having 1 to 40 carbon atoms and optionally including a heteroatom, or a hydrocarbyl group having 1 to 40 carbon atoms and optionally including a heteroatom, each R⁵ is the same as or different from each other, L is a single bond or a divalent linking group, X⁵ is a hydrogen atom, a halogen atom, a methyl group, or a trifluoromethyl group, and ( ) indicates a repeating unit.

Alternatively, the resist composition may include a silsesquioxane precursor represented by the following formula (6):

R⁶¹—Si(X⁶)₃ (6)
wherein R⁶¹ is a hydrogen atom, a hydrocarbyl carbonyl group having 1 to 40 carbon atoms and optionally including a heteroatom, or a hydrocarbyl group having 1 to 40 carbon atoms and optionally including a heteroatom, each R⁶¹ is the same as or different from each other, X⁶ is a hydrogen atom, a halogen atom, or a monovalent organic group represented by —O—R⁶², R⁶² is a hydrogen atom, a hydrocarbyl carbonyl group having 1 to 40 carbon atoms and optionally including a heteroatom, or a hydrocarbyl group having 1 to 40 carbon atoms and optionally including a heteroatom, and each X⁶ is the same as or different from each other.

Such a resist composition can be suitably used in the present invention.

In addition, in the step (3), the development can be dry development.

In the present invention, dry development makes it possible to suitably form a pattern.

### Advantageous Effects of Invention

The patterning process of the present invention is extremely useful for forming fine patterns in BEUV lithography because of achieving both high sensitivity and high resolution and excellent LWR.

### DESCRIPTION OF EMBODIMENTS

As described above, there has been a need for the development of a patterning process that is excellent in sensitivity, resolution, and LWR in photolithography using BEUV.

As a result of extensive research to achieve this object, the present inventors have found that a specific patterning process in BEUV lithography offers high sensitivity, excellent resolution, and LWR, and is extremely effective for precise microfabrication, leading to the creation of the present invention.

That is, the present invention is a patterning process including the steps of: (1) forming a resist film on a substrate or on an underlayer film stacked on a substrate; (2) exposing the resist film to BEUV light having a wavelength of 2 to 10 nm; and (3) developing the exposed resist film to form a resist pattern, in which the resist film contains a silsesquioxane compound.

The present invention is described in detail below, but is not limited thereto. Note that for convenience, the resist film used in the present invention will be described first, followed by the patterning process of the present invention.

### [Resist Film]

The resist film used in the present invention contains a silsesquioxane compound. Silicon atoms, the main component of silsesquioxane compounds, have a high molar absorption coefficient for BEUV light having a wavelength of 2 to 10 nm, thus allowing pattern formation with excellent sensitivity and resolution.

The resist film used in the present invention is not particularly limited as long as it contains a silsesquioxane compound.

The silsesquioxane compound is a compound including at least one of the repeating units represented by the following formula (0a) or (0b):

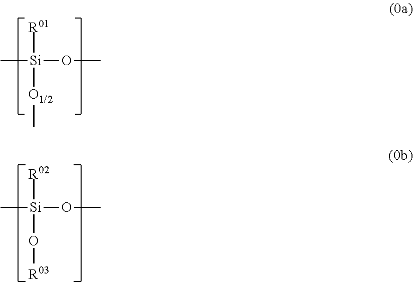

wherein R⁰¹, R⁰², and R⁰³ are each independently a hydrogen atom, a hydrocarbyl carbonyl group having 1 to 40 carbon atoms and optionally including a heteroatom, or a hydrocarbyl group having 1 to 40 carbon atoms and optionally including a heteroatom.

In formulae (0a) and (0b), R⁰¹, R⁰², and R⁰³ are each independently a hydrogen atom, a hydrocarbyl carbonyl group having 1 to 40 carbon atoms, preferably 1 to 20 carbon atoms, and optionally including a heteroatom, or a hydrocarbyl group having 1 to 40 carbon atoms, preferably 1 to 20 carbon atoms, and optionally including a heteroatom. The hydrocarbyl group and the hydrocarbyl portion of the hydrocarbyl carbonyl group may be saturated or unsaturated and may be linear, branched, or cyclic. Specific examples thereof include: alkyl groups having 1 to 20 carbon atoms such as a methyl group, an ethyl group, a n-propyl group, an isopropyl group, a n-butyl group, an isobutyl group, a sec-butyl group, a tert-butyl group, a tert-pentyl group, a n-pentyl group, a n-hexyl group, a n-octyl group, a 2-ethylhexyl group, a n-nonyl group, and a n-decyl group; cyclic saturated hydrocarbyl groups having 3 to 10 carbon atoms such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups having 2 to 20 carbon atoms such as a vinyl group and a 2-propenyl group; aryl groups having 6 to 20 carbon atoms such as a phenyl group and a naphthyl group; and groups obtained by combining these. In addition, a part or all of the hydrogen atoms in the hydrocarbyl group may be substituted with a group including a heteroatom such as an oxygen atom, a sulfur atom, a nitrogen atom, a halogen atom, and a silicon atom; a part of the —CH₂— in the hydrocarbyl group may be substituted with a group including a heteroatom such as an oxygen atom, a sulfur atom, a nitrogen atom, and a silicon atom; and as a result, a hydroxy group, a siloxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride, and the like may be included. In the formula, each R⁰¹, R⁰², and R⁰³ is the same as or different from each other.

In the formula (0a), —O_{1/2}— indicates that this oxygen atom is shared with another structural unit.

The silsesquioxane compound may include the only repeating unit represented by the formula (0a), may include the only repeating unit represented by the formula (0b), or may include both of the repeating unit represented by the formula (0a) and the repeating unit represented by the formula (0b). When the silsesquioxane compound includes the repeating unit represented by the formula (0a), the silsesquioxane compound may include only one type, or may include a plurality of types in which Rol is different. In addition, when the silsesquioxane compound includes the repeating unit represented by the formula (0b), the silsesquioxane compound may include only one type, or may include a plurality of types in which at least one of R⁰² and R⁰³ is different.

Depending on the bonding form of the formula (0a) or (0b), the silsesquioxane compound can take forms such as random silsesquioxanes, fully caged silsesquioxanes, partially caged silsesquioxanes, ladder-type silsesquioxanes, and polymeric silsesquioxanes.

Specific examples of the substituents represented by R⁰¹, R⁰², and R⁰³ in the formulae (0a) and (0b) include, but are not limited to, those shown below. Note that in the following formula, Me is a methyl group, and * represents an attachment point.

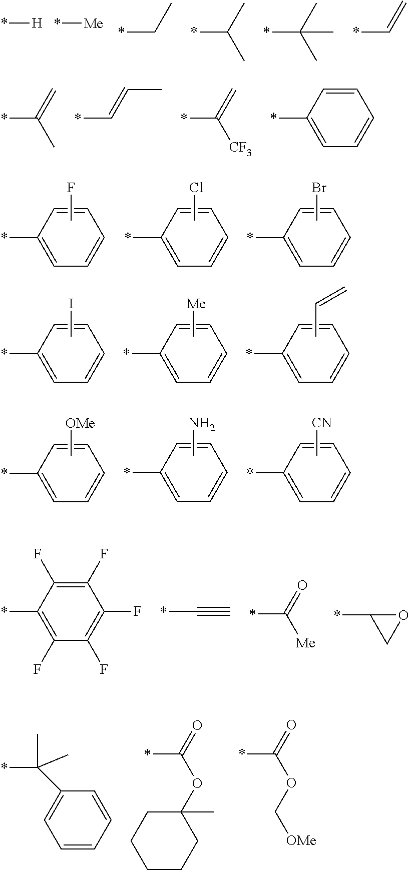

As described below, the resist film can include additives other than the silsesquioxane compound.

The step of forming the resist film is not particularly limited. For example, the resist film may be formed by CVD or ALD, or the resist film may be formed by applying a resist composition.

### [Formation of Resist Film by CVD or ALD]

The step of forming the resist film can be performed using chemical vapor deposition (CVD) or atomic layer deposition (ALD).

When a resist film is formed using CVD or ALD, the apparatus and approach used are not particularly limited, and for example, known techniques commonly used for forming resist films can be used.

When a resist film is formed using CVD or ALD, the source gas used is not particularly limited, and for example, the silsesquioxane compound itself can be used, or a precursor that will become silsesquioxane during film formation can be used, and it is preferable to use a precursor that will become silsesquioxane during film formation. The precursor is not particularly limited, but it is preferable to use a silicon compound represented by the following formula (0c):

R⁰⁴—Si(X⁰)₃ (0c)
wherein R⁰⁴ is a hydrogen atom, a hydrocarbyl carbonyl group having 1 to 40 carbon atoms and optionally including a heteroatom, or a hydrocarbyl group having 1 to 40 carbon atoms and optionally including a heteroatom; each R⁰⁴ is the same as or different from each other; X⁰ is a hydrogen atom, a halogen atom, or a monovalent organic group represented by —O—R⁰⁵; R⁰⁵ is a hydrogen atom, a hydrocarbyl carbonyl group having 1 to 40 carbon atoms and optionally including a heteroatom, or a hydrocarbyl group having 1 to 40 carbon atoms and optionally including a heteroatom; and each X⁰ is the same as or different from each other.

In the formula (c), R⁰⁴ is a hydrogen atom, a hydrocarbyl carbonyl group having 1 to 40 carbon atoms, preferably 1 to 20 carbon atoms, and optionally including a heteroatom, or a hydrocarbyl group having 1 to 40 carbon atoms, preferably 1 to 20 carbon atoms, and optionally including a heteroatom. The hydrocarbyl group and the hydrocarbyl portion of the hydrocarbyl carbonyl group may be saturated or unsaturated and may be linear, branched, or cyclic. Specific examples thereof include: alkyl groups having 1 to 20 carbon atoms such as a methyl group, an ethyl group, a n-propyl group, an isopropyl group, a n-butyl group, an isobutyl group, a sec-butyl group, a tert-butyl group, a tert-pentyl group, a n-pentyl group, a n-hexyl group, a n-octyl group, a 2-ethylhexyl group, a n-nonyl group, and a n-decyl group; cyclic saturated hydrocarbyl groups having 3 to 10 carbon atoms such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups having 2 to 20 carbon atoms such as a vinyl group and a 2-propenyl group; aryl groups having 6 to 20 carbon atoms such as a phenyl group and a naphthyl group; and groups obtained by combining these. In addition, a part or all of the hydrogen atoms in the hydrocarbyl group may be substituted with a group including a heteroatom such as an oxygen atom, a sulfur atom, a nitrogen atom, and a halogen atom; a part of the —CH₂— in the hydrocarbyl group may be substituted with a group including a heteroatom such as an oxygen atom, a sulfur atom, a nitrogen atom, and a silicon atom; and as a result, a hydroxy group, a siloxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride, and the like may be included.

In the formula (0c), X⁰ is a hydrogen atom, a halogen atom, or a monovalent organic group represented by —O—R⁰⁵. Specific examples of halogen atoms include fluorine, chlorine, bromine, iodine, and astatine. R⁰⁵ is a hydrogen atom, a hydrocarbyl carbonyl group having 1 to 40 carbon atoms, preferably 1 to 20 carbon atoms, and optionally including a heteroatom, or a hydrocarbyl group having 1 to 40 carbon atoms, preferably 1 to 20 carbon atoms, and optionally including a heteroatom. The hydrocarbyl group and the hydrocarbyl portion of the hydrocarbyl carbonyl group may be saturated or unsaturated and may be linear, branched, or cyclic. Specific examples thereof include: alkyl groups having 1 to 20 carbon atoms such as a methyl group, an ethyl group, a n-propyl group, an isopropyl group, a n-butyl group, an isobutyl group, a sec-butyl group, a tert-butyl group, a tert-pentyl group, a n-pentyl group, a n-hexyl group, a n-octyl group, a 2-ethylhexyl group, a n-nonyl group, and a n-decyl group; cyclic saturated hydrocarbyl groups having 3 to 10 carbon atoms such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups having 2 to 20 carbon atoms such as a vinyl group and a 2-propenyl group; aryl groups having 6 to 20 carbon atoms such as a phenyl group and a naphthyl group; and groups obtained by combining these. In addition, a part or all of the hydrogen atoms in the hydrocarbyl group may be substituted with a group including a heteroatom such as an oxygen atom, a sulfur atom, a nitrogen atom, and a halogen atom; a part of the —CH₂— in the hydrocarbyl group may be substituted with a group including a heteroatom such as an oxygen atom, a sulfur atom, a nitrogen atom, and a silicon atom; and as a result, a hydroxy group, a siloxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride, and the like may be included. In the formula, each X⁰ is the same as or different from each other. In addition, when a plurality of monovalent organic groups represented by —O—R⁰⁵ are included, each R⁰⁵ is the same as or different from each other.

Specific examples of the precursor represented by the formula (0c) include, but are not limited to, those shown below. Note that in the following formulae, Me is a methyl group.

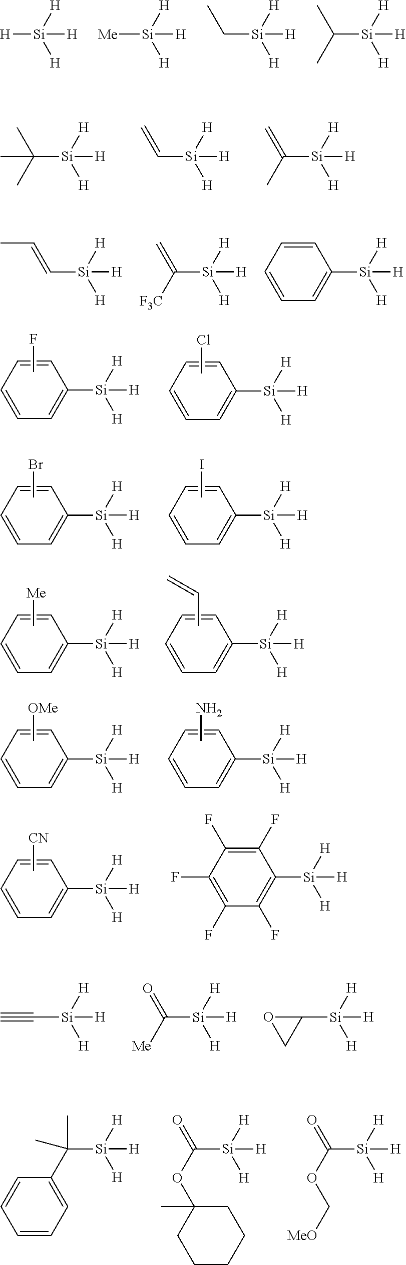

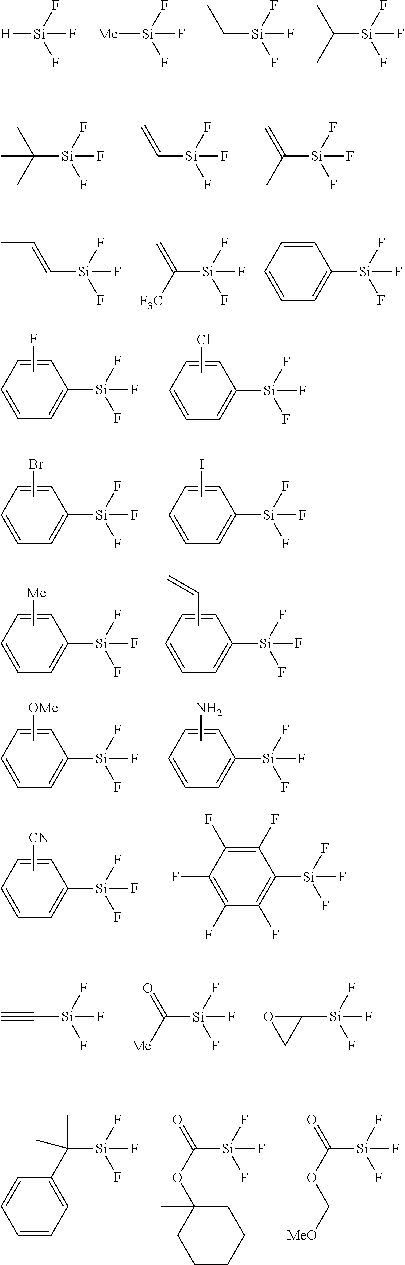

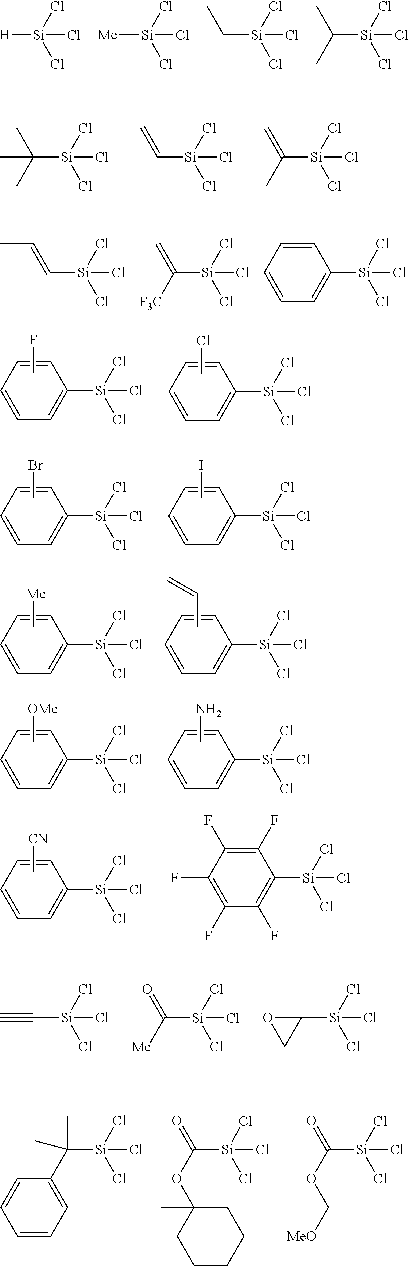

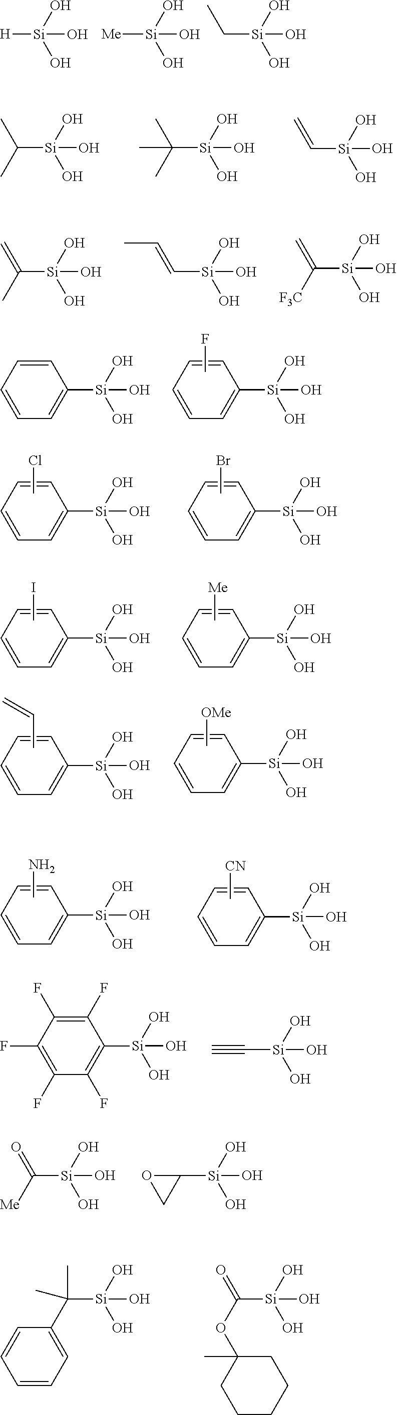

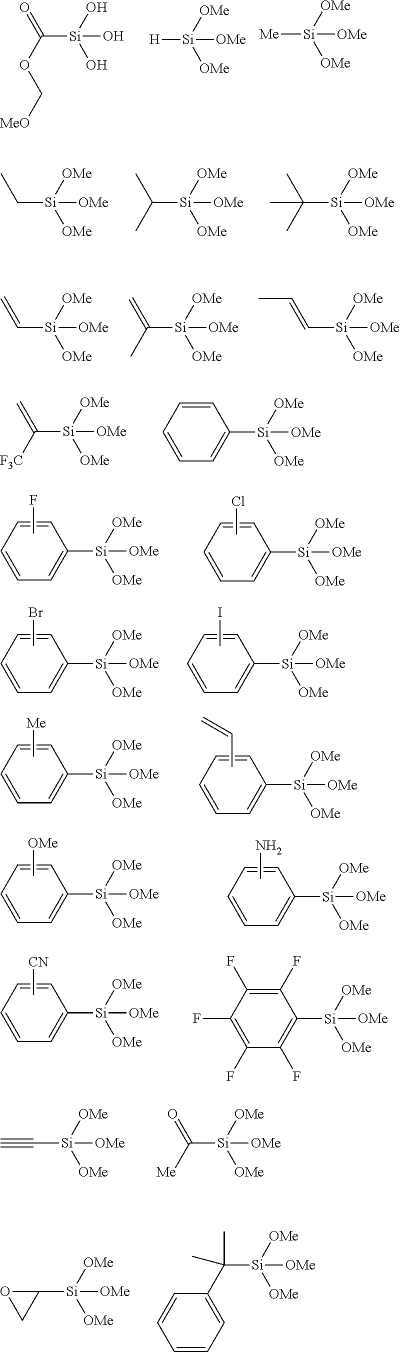

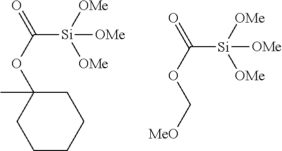 [SMILES: CO[Si](OC)(OC)C(=O)OC1(C)CCCCC1 ; COCOC(=O)[Si](OC)(OC)OC]

When a resist film is formed using CVD or ALD, in addition to the above-described source gases, other gases may be used. The other gases that can be used are not particularly limited, but examples thereof include nitrogen, helium, argon, water, alcohol, ether, oxygen, ozone, carbon monoxide, carbon dioxide, hydrogen peroxide, carboxylic acid, nitrogen oxide, sulfur oxide, ammonia, hydrogen, halogen, hydrogen halide, hydrocarbon, halogenated hydrocarbon, silane, alkylsilane, halogenated silane, silicate ester, silicic acid, nitric acid, sulfuric acid, nitrous acid, sulfurous acid, phosphoric acid, phosphorous acid, hypophosphorous acid, and carboxylic acid. These gases can also be used in combination.

### [Formation of Resist Film Using Resist Composition]

The step of forming the resist film can include a step of applying a resist composition.

When the step of applying a resist composition is included, the apparatus and approach used are not particularly limited, and for example, known techniques commonly used for forming resist films can be used.

### [Resist Composition]

The resist composition used in the present invention is not particularly limited as long as it contains a silsesquioxane compound or a silsesquioxane precursor. The silsesquioxane compound or silsesquioxane precursor is also not particularly limited, and those obtained according to conventionally known manufacturing methods may be used.

The silsesquioxane compound or silsesquioxane precursor in the resist composition is preferably represented by the following formulae (1) to (6).

The resist composition can include a fully caged silsesquioxane compound represented by the following formula (1):

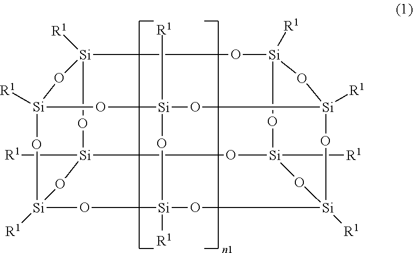

wherein “n1” is an integer of 0 to 40; R¹ is a hydrogen atom, a hydrocarbyl carbonyl group having 1 to 40 carbon atoms and optionally including a heteroatom, or a hydrocarbyl group having 1 to 40 carbon atoms and optionally including a heteroatom; and each R¹ is the same as or different from each other.

In the formula (1), “n1” is an integer of 0 to 40. “n1” is preferably 0 to 10, more preferably 0 to 5, still more preferably 0 to 4, further more preferably 0 to 3, particularly preferably 0 to 2, and most preferably 0 or 1.

In the formula (1), each R¹ is each independently a hydrogen atom, a hydrocarbyl carbonyl group having 1 to 40 carbon atoms, preferably 1 to 20 carbon atoms, and optionally including a heteroatom, or a hydrocarbyl group having 1 to 40 carbon atoms, preferably 1 to 20 carbon atoms, and optionally including a heteroatom. The hydrocarbyl group and the hydrocarbyl portion of the hydrocarbyl carbonyl group may be saturated or unsaturated and may be linear, branched, or cyclic. Specific examples thereof include: alkyl groups having 1 to 20 carbon atoms such as a methyl group, an ethyl group, a n-propyl group, an isopropyl group, a n-butyl group, an isobutyl group, a sec-butyl group, a tert-butyl group, a tert-pentyl group, a n-pentyl group, a n-hexyl group, a n-octyl group, a 2-ethylhexyl group, a n-nonyl group, and a n-decyl group; cyclic saturated hydrocarbyl groups having 3 to 10 carbon atoms such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups having 2 to 20 carbon atoms such as a vinyl group and a 2-propenyl group; aryl groups having 6 to 20 carbon atoms such as a phenyl group and a naphthyl group; and groups obtained by combining these. In addition, a part or all of the hydrogen atoms in the hydrocarbyl group may be substituted with a group including a heteroatom such as an oxygen atom, a sulfur atom, a nitrogen atom, and a halogen atom; a part of the —CH₂— in the hydrocarbyl group may be substituted with a group including a heteroatom such as an oxygen atom, a sulfur atom, a nitrogen atom, and a silicon atom; and as a result, a hydroxy group, a siloxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride, and the like may be included. In the formula, each R¹ is the same as or different from each other. R¹ is preferably a hydrocarbyl carbonyl group having 1 to 20 carbon atoms, or a hydrocarbyl group having 1 to 20 carbon atoms and optionally including a heteroatom.

When the resist composition includes a fully caged silsesquioxane compound represented by the formula (1), a single compound may be used, or a plurality of compounds with different n1 and R¹ may be used.

Specific examples of fully caged silsesquioxane compounds represented by the formula (1) include, but are not limited to, those shown below. Note that in the following formulae, Me is a methyl group, and Ph is a phenyl group.

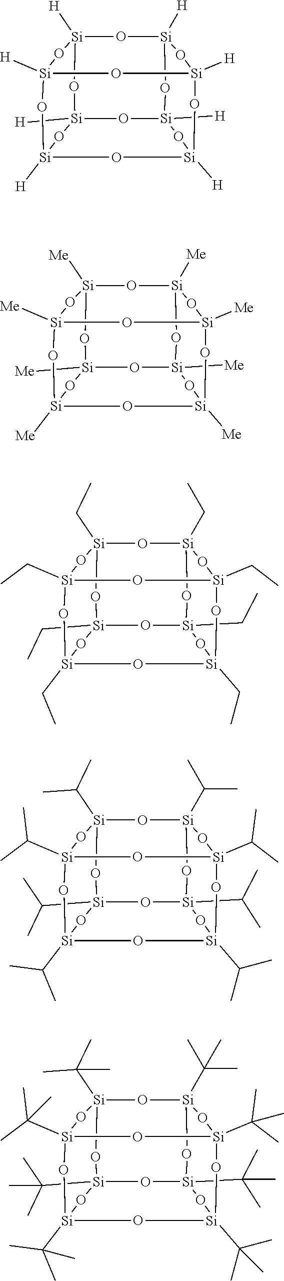

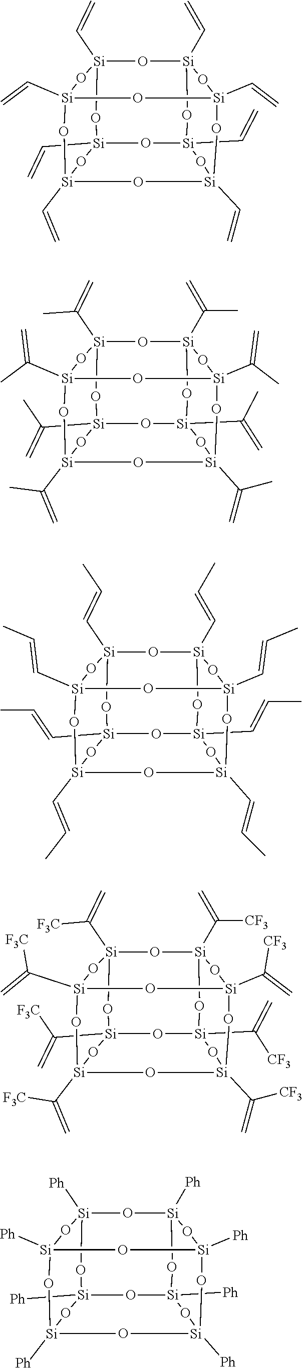

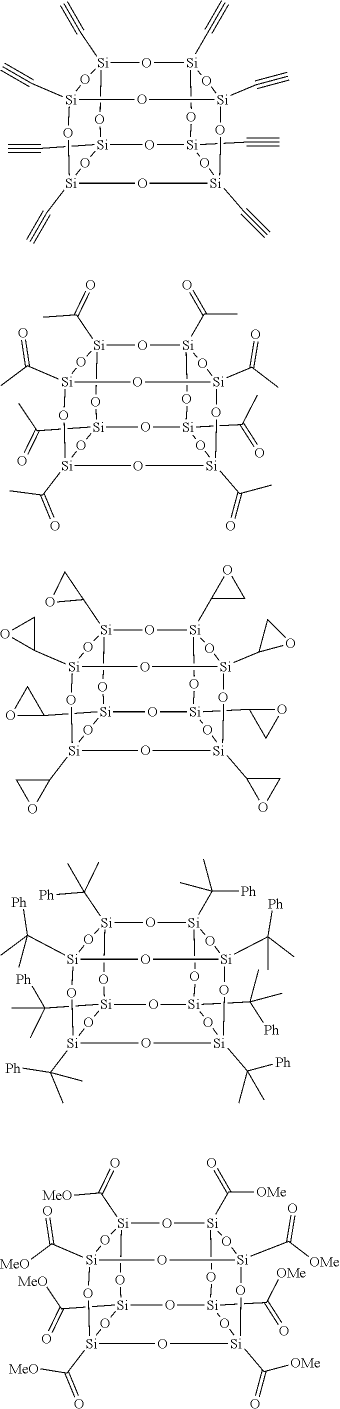

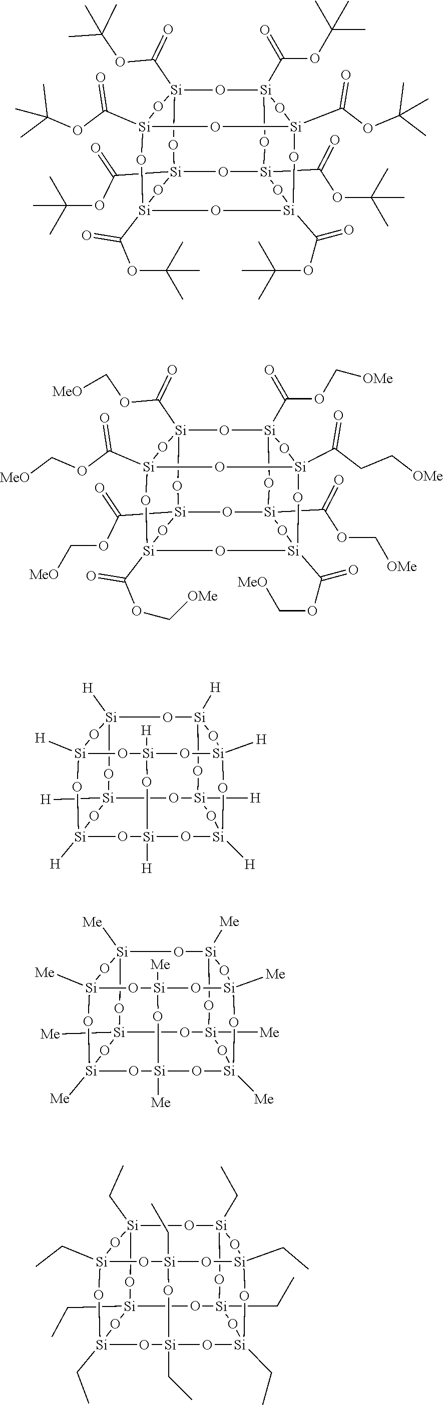

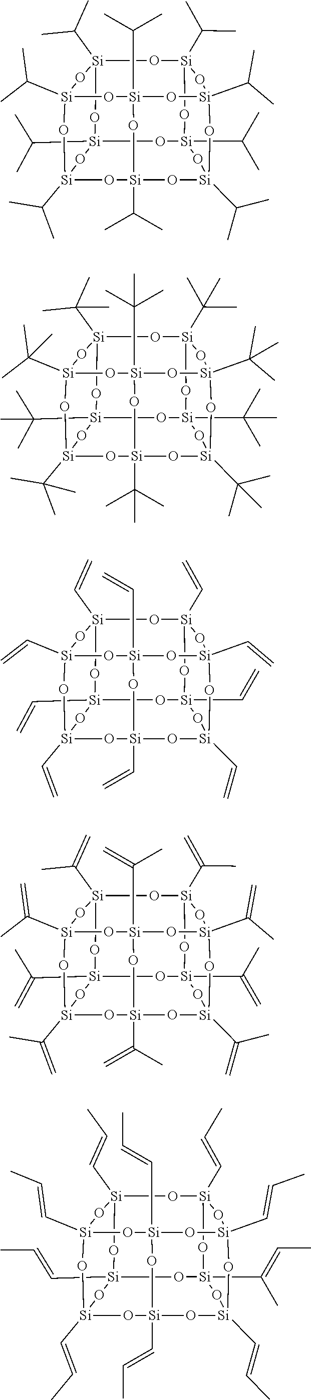

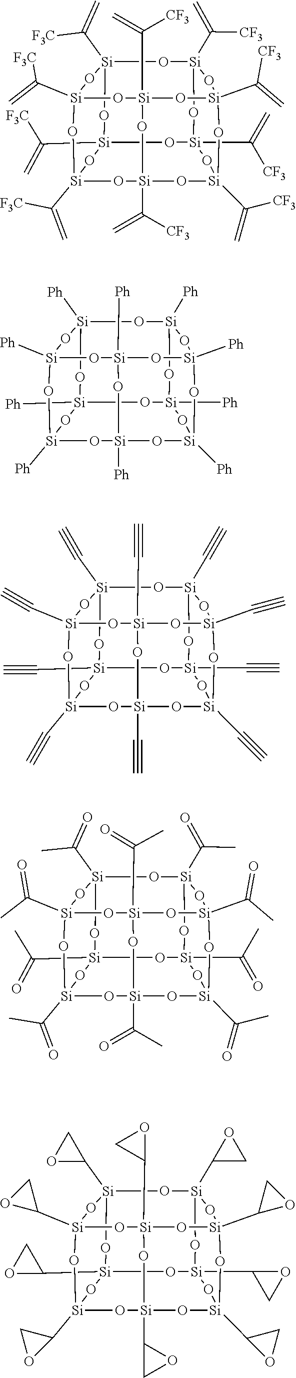

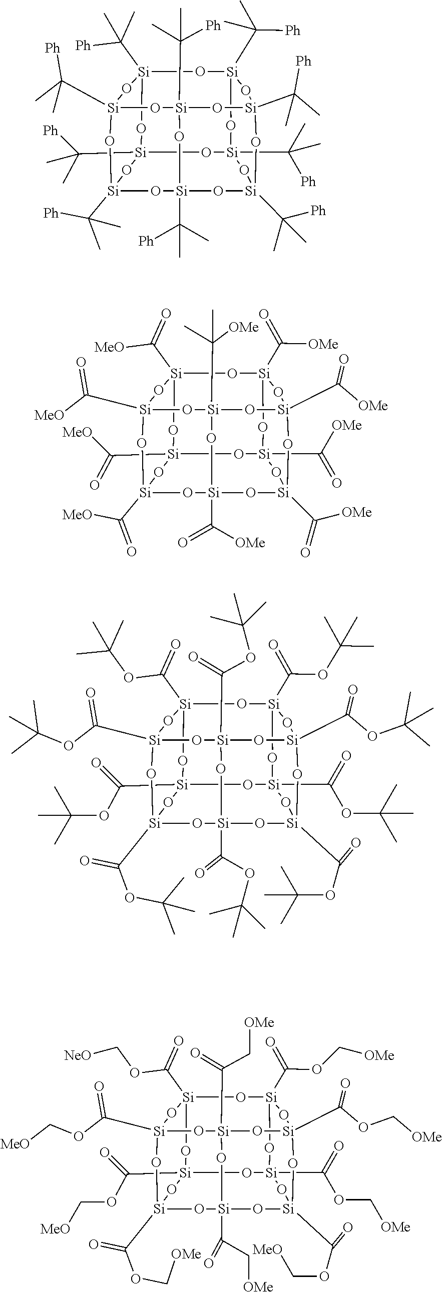

The resist composition can include a partially caged silsesquioxane compound represented by the following formula (2):

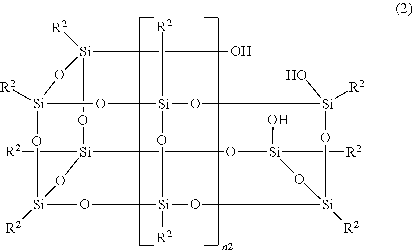

wherein “n2” is an integer of 0 to 40; R² is a hydrogen atom, a hydrocarbyl carbonyl group having 1 to 40 carbon atoms and optionally including a heteroatom, or a hydrocarbyl group having 1 to 40 carbon atoms and optionally including a heteroatom; and each R² is the same as or different from each other.

In the formula (2), “n2” is an integer of 0 to 40. “n2” is preferably 0 to 10, more preferably 0 to 5, still more preferably 0 to 4, further more preferably 0 to 3, particularly preferably 0 to 2, and most preferably 0 or 1.

In the formula (2), each R² is each independently a hydrogen atom, a hydrocarbyl carbonyl group having 1 to 40 carbon atoms, preferably 1 to 20 carbon atoms, and optionally including a heteroatom, or a hydrocarbyl group having 1 to 40 carbon atoms, preferably 1 to 20 carbon atoms, and optionally including a heteroatom. The hydrocarbyl group and the hydrocarbyl portion of the hydrocarbyl carbonyl group may be saturated or unsaturated and may be linear, branched, or cyclic. Specific examples thereof include: alkyl groups having 1 to 20 carbon atoms such as a methyl group, an ethyl group, a n-propyl group, an isopropyl group, a n-butyl group, an isobutyl group, a sec-butyl group, a tert-butyl group, a tert-pentyl group, a n-pentyl group, a n-hexyl group, a n-octyl group, a 2-ethylhexyl group, a n-nonyl group, and a n-decyl group; cyclic saturated hydrocarbyl groups having 3 to 10 carbon atoms such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups having 2 to 20 carbon atoms such as a vinyl group and a 2-propenyl group; aryl groups having 6 to 20 carbon atoms such as a phenyl group and a naphthyl group; and groups obtained by combining these. In addition, a part or all of the hydrogen atoms in the hydrocarbyl group may be substituted with a group including a heteroatom such as an oxygen atom, a sulfur atom, a nitrogen atom, and a halogen atom; a part of the —CH₂— in the hydrocarbyl group may be substituted with a group including a heteroatom such as an oxygen atom, a sulfur atom, a nitrogen atom, and a silicon atom; and as a result, a hydroxy group, a siloxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride, and the like may be included. In the formula, each R² is the same as or different from each other.

When the resist composition includes a partially caged silsesquioxane compound represented by the formula (2), a single compound may be used, or a plurality of compounds with different n2 and R² may be used.

Specific examples of partially caged silsesquioxane compounds represented by the formula (2) include, but are not limited to, those shown below. Note that in the following formulae, Me is a methyl group, and Ph is a phenyl group.

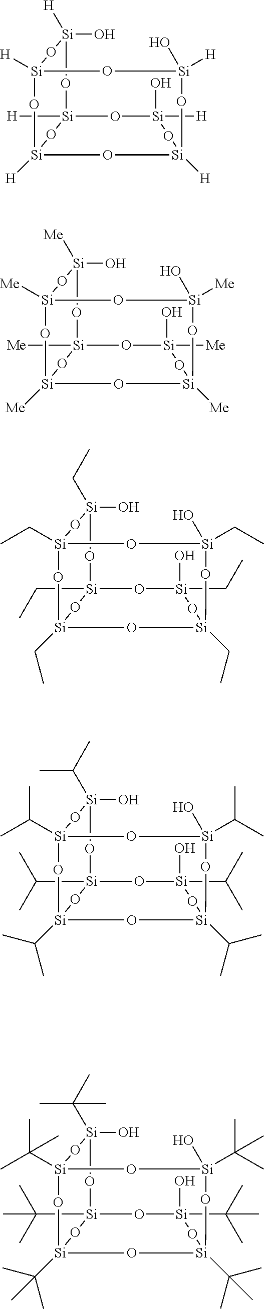

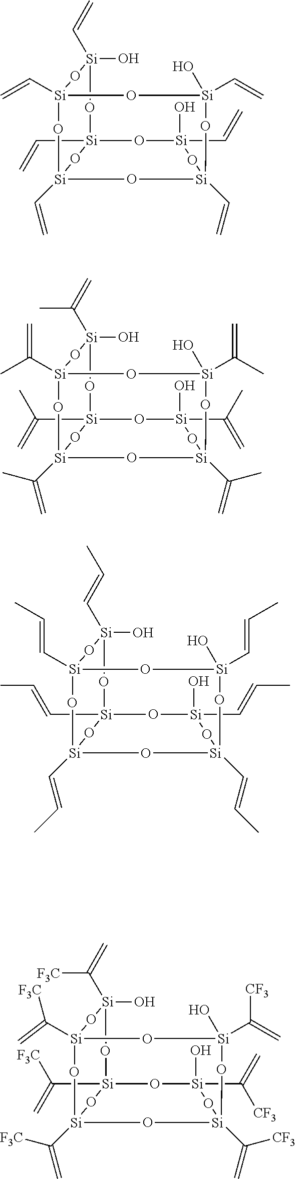

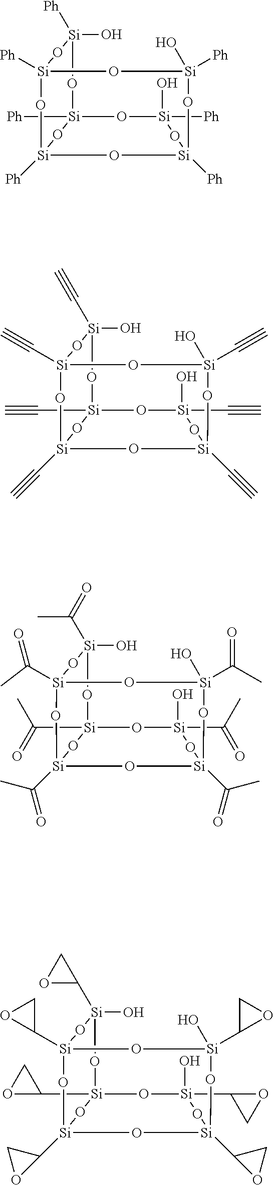

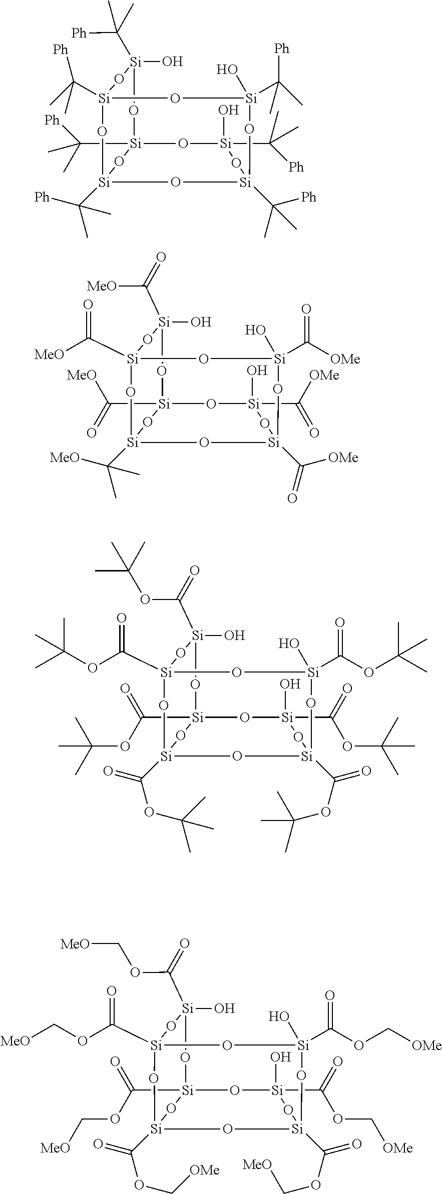

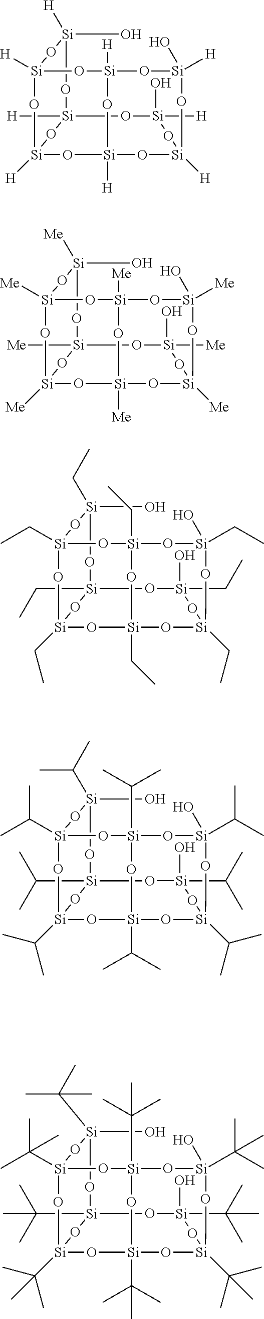

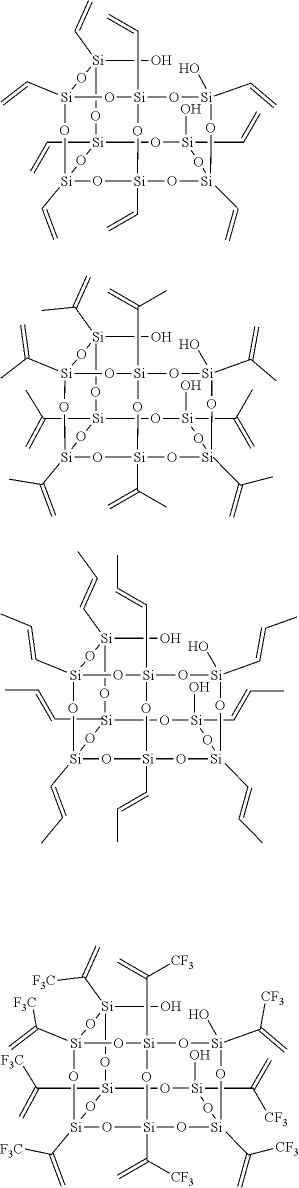

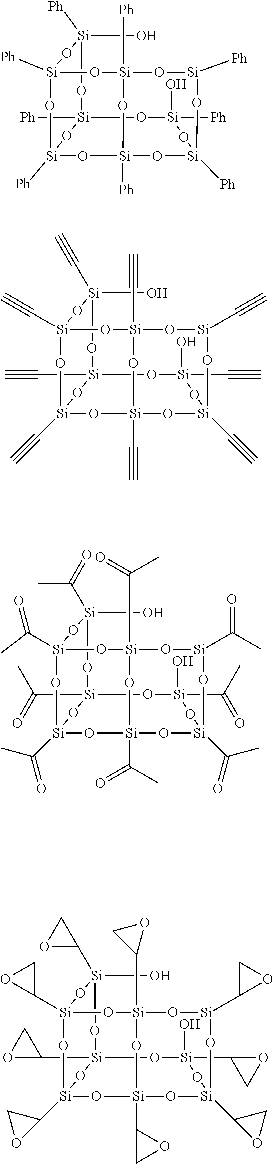

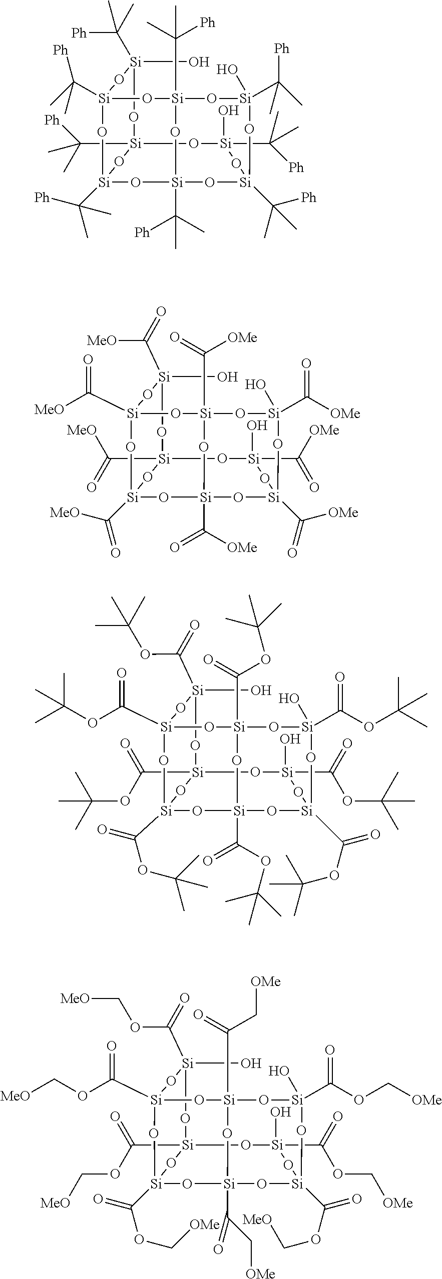

The resist composition can include a ladder-type silsesquioxane compound represented by the following formula (3):

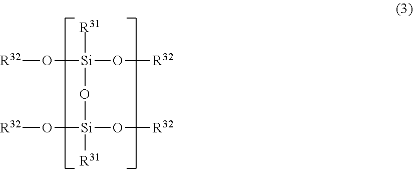

wherein R³¹ is a hydrogen atom, a hydrocarbyl carbonyl group having 1 to 40 carbon atoms and optionally including a heteroatom, or a hydrocarbyl group having 1 to 40 carbon atoms and optionally including a heteroatom; each R³¹ is the same as or different from each other; R³² is a hydrogen atom, a hydrocarbyl carbonyl group having 1 to 40 carbon atoms and optionally including a heteroatom, or a hydrocarbyl group having 1 to 40 carbon atoms and optionally including a heteroatom; each R³² is the same as or different from each other; and [ ] indicates a repeating unit.

In the formula (3), R³¹ and R³² are each independently a hydrogen atom, a hydrocarbyl carbonyl group having 1 to 40 carbon atoms, preferably 1 to 20 carbon atoms, and optionally including a heteroatom, or a hydrocarbyl group having 1 to 40 carbon atoms, preferably 1 to 20 carbon atoms, and optionally including a heteroatom. The hydrocarbyl group and the hydrocarbyl portion of the hydrocarbyl carbonyl group may be saturated or unsaturated and may be linear, branched, or cyclic. Specific examples thereof include: alkyl groups having 1 to 20 carbon atoms such as a methyl group, an ethyl group, a n-propyl group, an isopropyl group, a n-butyl group, an isobutyl group, a sec-butyl group, a tert-butyl group, a tert-pentyl group, a n-pentyl group, a n-hexyl group, a n-octyl group, a 2-ethylhexyl group, a n-nonyl group, and a n-decyl group; cyclic saturated hydrocarbyl groups having 3 to 10 carbon atoms such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups having 2 to 20 carbon atoms such as a vinyl group and a 2-propenyl group; aryl groups having 6 to 20 carbon atoms such as a phenyl group and a naphthyl group; and groups obtained by combining these. In addition, a part or all of the hydrogen atoms in the hydrocarbyl group may be substituted with a group including a heteroatom such as an oxygen atom, a sulfur atom, a nitrogen atom, and a halogen atom; a part of the —CH₂— in the hydrocarbyl group may be substituted with a group including a heteroatom such as an oxygen atom, a sulfur atom, a nitrogen atom, and a silicon atom; and as a result, a hydroxy group, a siloxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride, and the like may be included. In the formula, each R³¹ and each R³² is the same as or different from each other.

Specific examples of the substituents represented by R³¹ and R³² in the formula (3) include, but are not limited to, those shown below. Note that in the following formulae, Me is a methyl group, and * represents an attachment point.

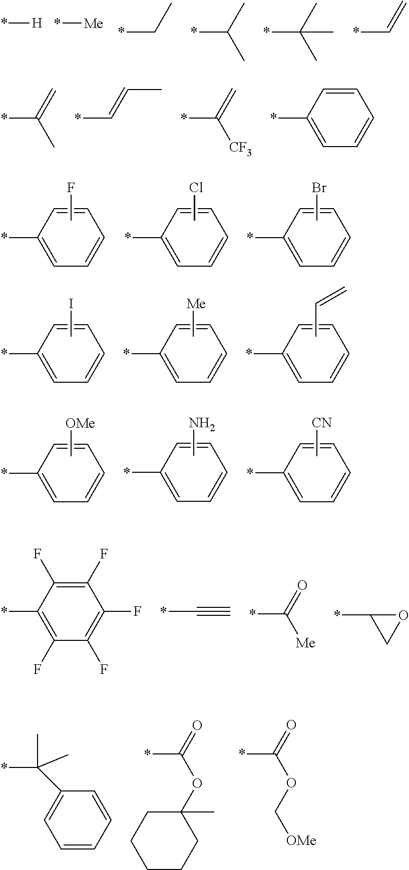

The weight-average molecular weight (Mw) of the ladder-type silsesquioxane compound having a repeating unit represented by the formula (3) is not particularly limited, and for example, 500 or more, preferably 800 or more, more preferably 1,000 to 20,000, still more preferably 2,000 to 10,000, and particularly preferably 3,000 to 7,000. Note that in the present invention, the weight-average molecular weight Mw and number-average molecular weight Mn are values measured in terms of polystyrene by gel permeation chromatography (GPC) using tetrahydrofuran (THF) as a solvent. GPC measurements are typically performed at room temperature, around 23° C., but may also be performed at higher or lower temperatures.

The dispersity (Mw/Mn) of the ladder-type silsesquioxane compound represented by the formula (3) is preferably a narrow dispersity of 1.00 to 2.00. Mw/Mn is preferably more than 1.30, and the lower limit may be 1.40, 1.50, or 1.60 and the upper limit may be 1.70, 1.80, or 1.90.

When the resist composition includes the ladder-type silsesquioxane compound represented by the formula (3), a single compound may be used, or a plurality of compounds with different molecular weights or different R³¹ and R³² may be used.

The resist composition can include a silsesquioxane resin having a repeating unit represented by the following formula (4a) or (4b):

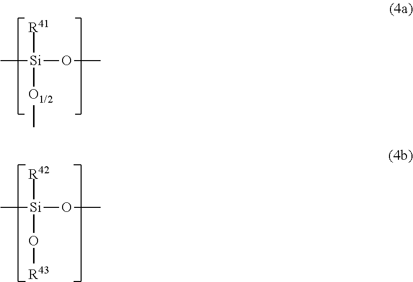

wherein R⁴¹, R⁴², and R⁴³ are each independently a hydrogen atom, a hydrocarbyl carbonyl group having 1 to 40 carbon atoms and optionally including a heteroatom, or a hydrocarbyl group having 1 to 40 carbon atoms and optionally including a heteroatom.

In the formulae (4a) and (4b), R⁴¹, R⁴², and R⁴³ are each independently a hydrogen atom, a hydrocarbyl carbonyl group having 1 to 40 carbon atoms, preferably 1 to 20 carbon atoms, and optionally including a heteroatom, or a hydrocarbyl group having 1 to 40 carbon atoms, preferably 1 to 20 carbon atoms, and optionally including a heteroatom. The hydrocarbyl group and the hydrocarbyl portion of the hydrocarbyl carbonyl group may be saturated or unsaturated and may be linear, branched, or cyclic. Specific examples thereof include: alkyl groups having 1 to 20 carbon atoms such as a methyl group, an ethyl group, a n-propyl group, an isopropyl group, a n-butyl group, an isobutyl group, a sec-butyl group, a tert-butyl group, a tert-pentyl group, a n-pentyl group, a n-hexyl group, a n-octyl group, a 2-ethylhexyl group, a n-nonyl group, and a n-decyl group; cyclic saturated hydrocarbyl groups having 3 to 10 carbon atoms such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups having 2 to 20 carbon atoms such as a vinyl group and a 2-propenyl group; aryl groups having 6 to 20 carbon atoms such as a phenyl group and a naphthyl group; and groups obtained by combining these. In addition, a part or all of the hydrogen atoms in the hydrocarbyl group may be substituted with a group including a heteroatom such as an oxygen atom, a sulfur atom, a nitrogen atom, and a halogen atom; a part of the —CH₂— in the hydrocarbyl group may be substituted with a group including a heteroatom such as an oxygen atom, a sulfur atom, a nitrogen atom, and a silicon atom; and as a result, a hydroxy group, a siloxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride, and the like may be included. In the formula, each R⁴¹, R⁴², and R⁴³ is the same as or different from each other.

In the formula (4a), —O_{1/2}— indicates that this oxygen atom is shared with another structural unit.

The silsesquioxane resin having repeating units represented by the formula (4a) or (4b) may include only the repeating unit represented by the formula (4a), may include only the repeating unit represented by the formula (4b), or may include both the repeating unit represented by formula (4a) and the repeating unit represented by the formula (4b). When both repeating units are included, the ratio of each repeating unit may be arbitrary. The silsesquioxane compound including the repeating unit represented by the formula (4a) may include only one type, or may include a plurality of types in which R⁴¹ is different. In addition, the silsesquioxane compound including the repeating unit represented by the formula (4b) may include only one type, or may include a plurality of types in which at least one of R⁴² and R⁴³ is different. In the silsesquioxane resin having a repeating unit represented by the formula (4a) or (4b), the content ratio (molar ratio) between the repeating unit represented by the formula (4a) and the repeating unit represented by the formula (4b) is preferably repeating unit represented by formula (4a):repeating unit represented by formula (4b)=0:100 to 100:0, more preferably 0.01:99.99 to 100:0, still more preferably 0.01:99.99 to 50:50, further more preferably 1:99 to 50:50, and particularly preferably 10:90 to 50:50.

Specific examples of the substituents represented by R⁴¹, R⁴², and R⁴³ in the formulae (4a) and (4b) include, but are not limited to, those shown below. Note that in the following formulae, Me is a methyl group, and * represents an attachment point.

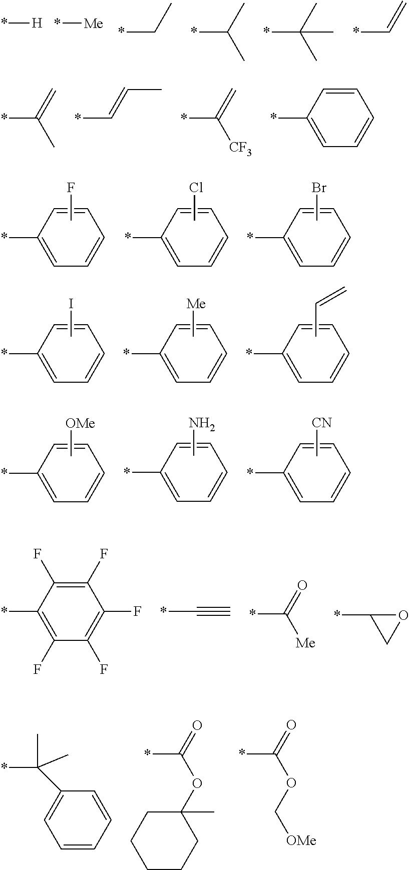

The weight-average molecular weight (Mw) of the silsesquioxane resin having a repeating units represented by the formula (4a) or (4b) is not particularly limited, but is preferably 800 or more, more preferably 1,000 to 20,000, still more preferably 2,000 to 10,000, and particularly preferably 3,000 to 7,000.

The dispersity (Mw/Mn) of the silsesquioxane resin having a repeating unit represented by the formula (4a) or (4b) is preferably a narrow dispersity of 1.00 to 2.00. Mw/Mn is preferably more than 1.30, and the lower limit may be 1.40, 1.50, or 1.60 and the upper limit may be 1.70, 1.80, or 1.90.

When the resist composition includes a silsesquioxane resin having a repeating unit represented by the formula (4a) or (4b), a single resin may be used, or a plurality of resins with different molecular weights or different R⁴¹, R⁴², and R⁴³ may be used.

The resist composition can include a polymer having a repeating unit represented by the following formula (5):

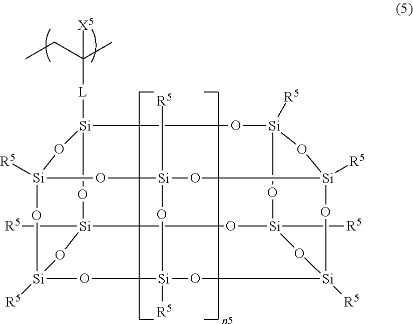

wherein “n5” is an integer of 0 to 40; R⁵ is a hydrogen atom, a hydrocarbyl carbonyl group having 1 to 40 carbon atoms and optionally including a heteroatom, or a hydrocarbyl group having 1 to 40 carbon atoms and optionally including a heteroatom; each R⁵ is the same as or different from each other; L is a single bond or a divalent linking group; X⁵ is a hydrogen atom, a halogen atom, a methyl group, or a trifluoromethyl group; and ( ) indicates a repeating unit.

In the formula (5), “n5” is an integer of 0 to 40. “n5” is preferably 0 to 10, more preferably 0 to 5, still more preferably 0 to 4, further more preferably 0 to 3, particularly preferably 0 to 2, and most preferably 0 or 1.

In the formula (5), each R⁵ is each independently a hydrogen atom, a hydrocarbyl carbonyl group having 1 to 40 carbon atoms, preferably 1 to 20 carbon atoms, and optionally including a heteroatom, or a hydrocarbyl group having 1 to 40 carbon atoms, preferably 1 to 20 carbon atoms, and optionally including a heteroatom. The hydrocarbyl group and the hydrocarbyl portion of the hydrocarbyl carbonyl group may be saturated or unsaturated and may be linear, branched, or cyclic. Specific examples thereof include: alkyl groups having 1 to 20 carbon atoms such as a methyl group, an ethyl group, a n-propyl group, an isopropyl group, a n-butyl group, an isobutyl group, a sec-butyl group, a tert-butyl group, a tert-pentyl group, a n-pentyl group, a n-hexyl group, a n-octyl group, a 2-ethylhexyl group, a n-nonyl group, and a n-decyl group; cyclic saturated hydrocarbyl groups having 3 to 10 carbon atoms such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups having 2 to 20 carbon atoms such as a vinyl group and a 2-propenyl group; aryl groups having 6 to 20 carbon atoms such as a phenyl group and a naphthyl group; and groups obtained by combining these. In addition, a part or all of the hydrogen atoms in the hydrocarbyl group may be substituted with a group including a heteroatom such as an oxygen atom, a sulfur atom, a nitrogen atom, and a halogen atom; a part of the —CH₂— in the hydrocarbyl group may be substituted with a group including a heteroatom such as an oxygen atom, a sulfur atom, a nitrogen atom, and a silicon atom; and as a result, a hydroxy group, a siloxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride, and the like may be included. In the formula, each R⁵ is the same as or different from each other.

In the formula (5), X⁵ is a hydrogen atom, a halogen atom, a methyl group, or a trifluoromethyl group. L is a single bond or a divalent linking group. Preferably, the divalent linking group is a phenylene group, a naphthylene group, or *—C(═O)—O-L¹-. L¹ is a saturated hydrocarbylene group having 1 to 10 carbon atoms, a phenylene group, or a naphthylene group, and the saturated hydrocarbylene group may include a hydroxy group, an ether bond, an ester bond, or a lactone ring. * represents an attachment point to a carbon atom in the main chain.

Specific examples of the repeating unit represented by the formula (5) include, but are not limited to, those shown below. Note that in the following formulae, Me is a methyl group, and Ph is a phenyl group.

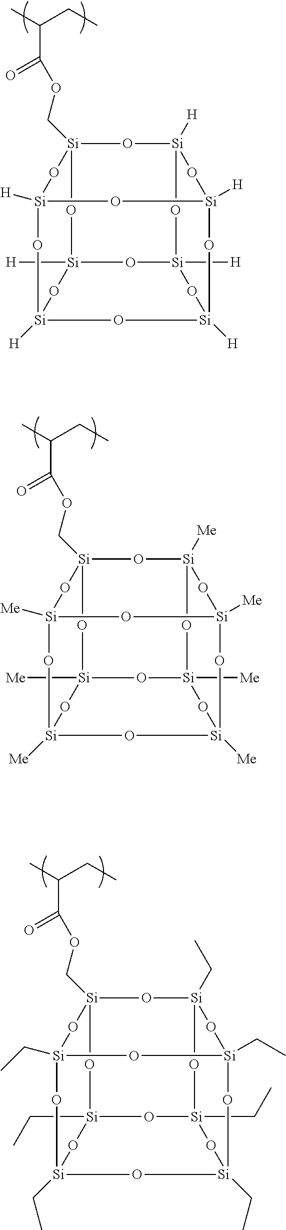

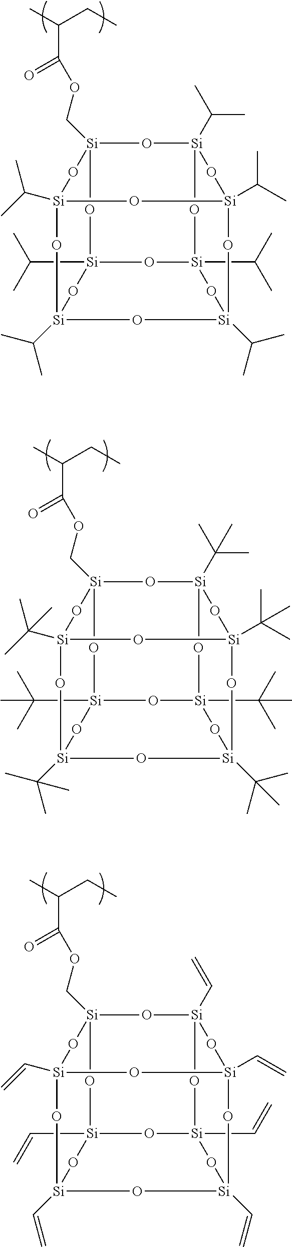

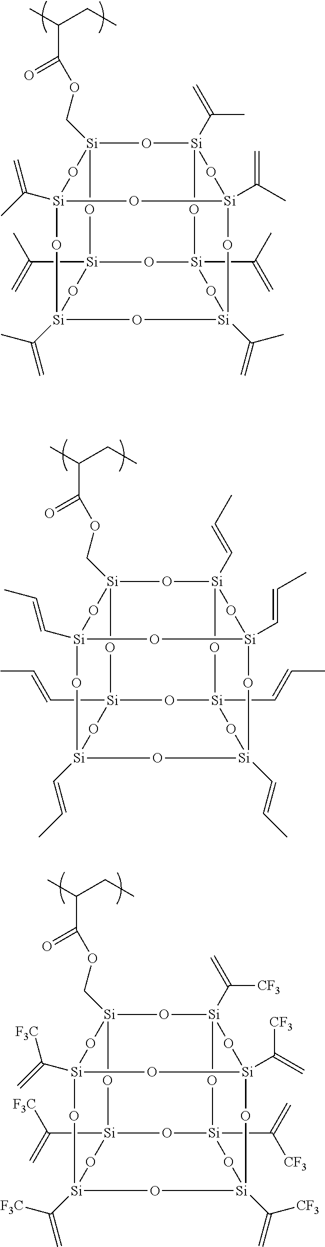

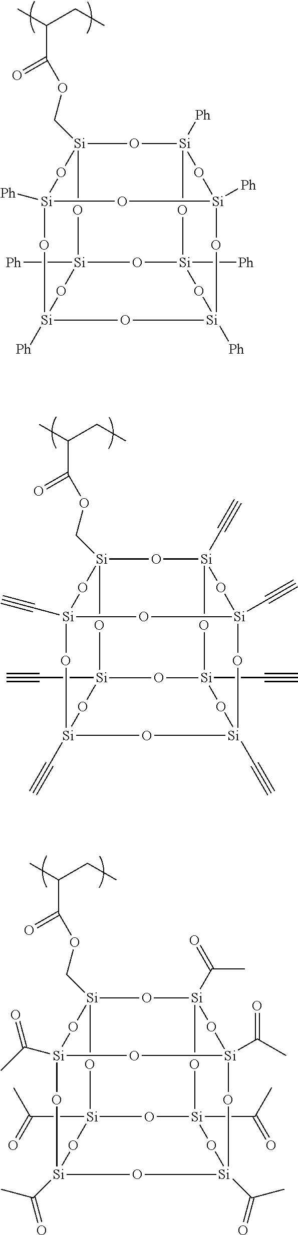

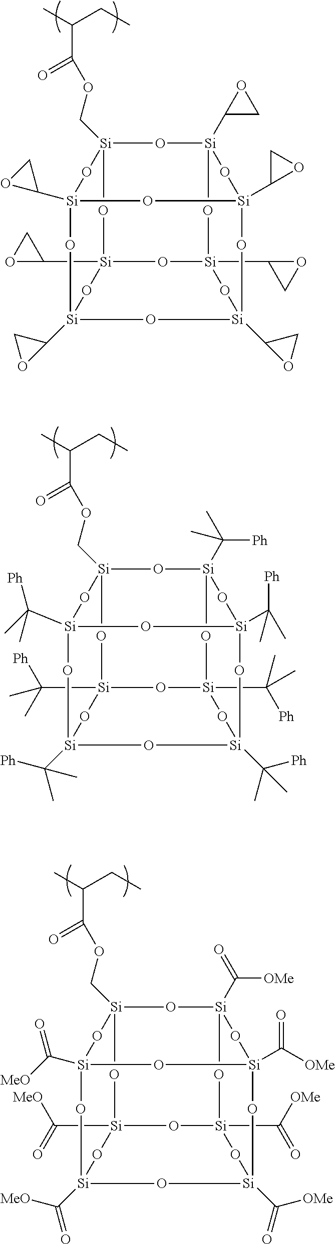

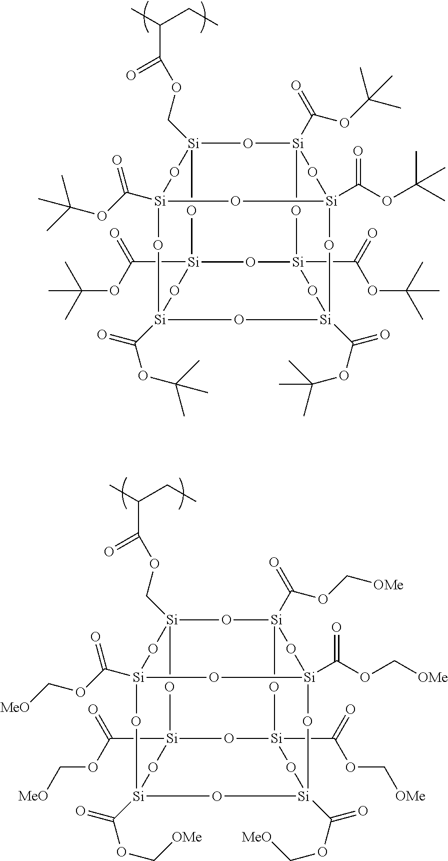

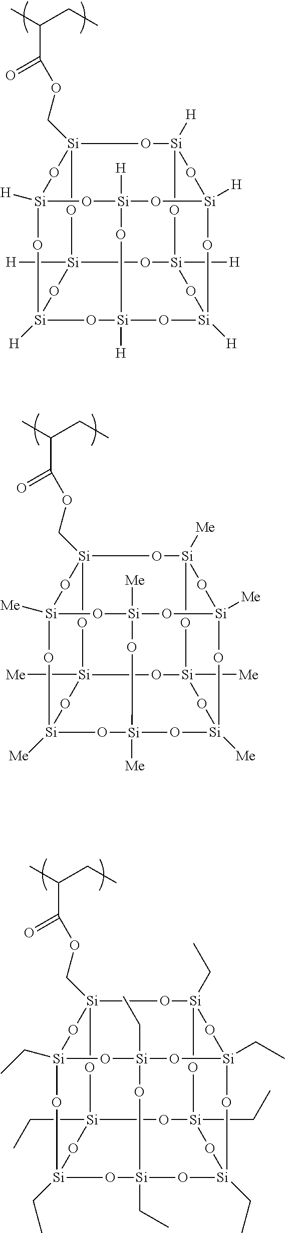

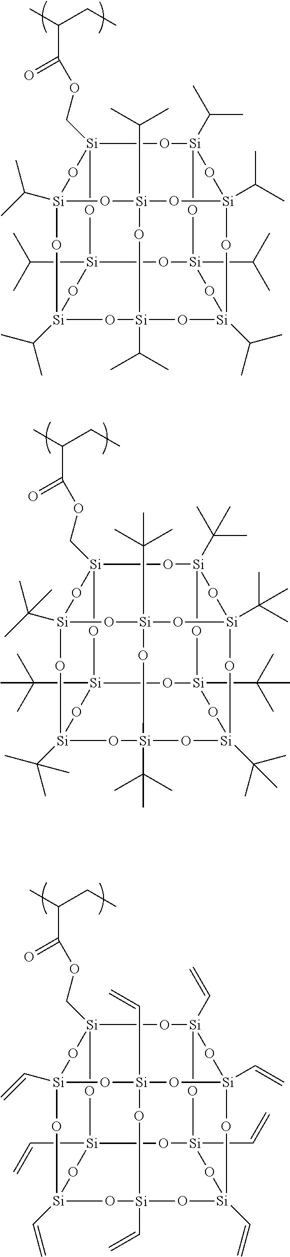

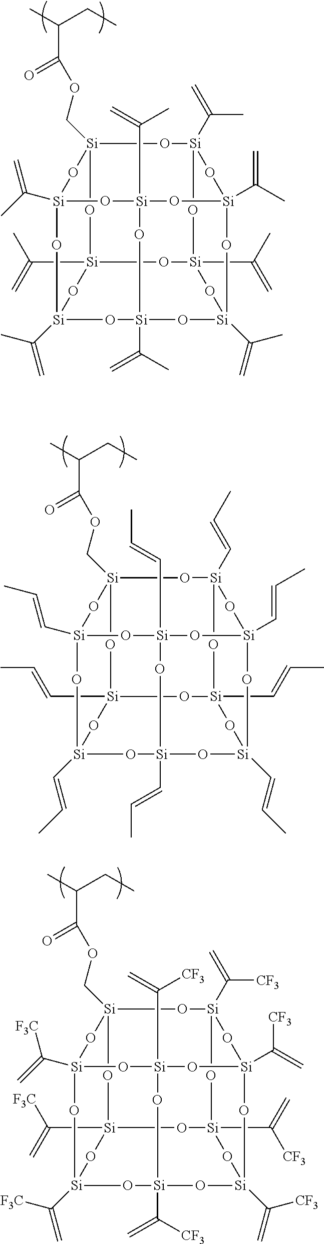

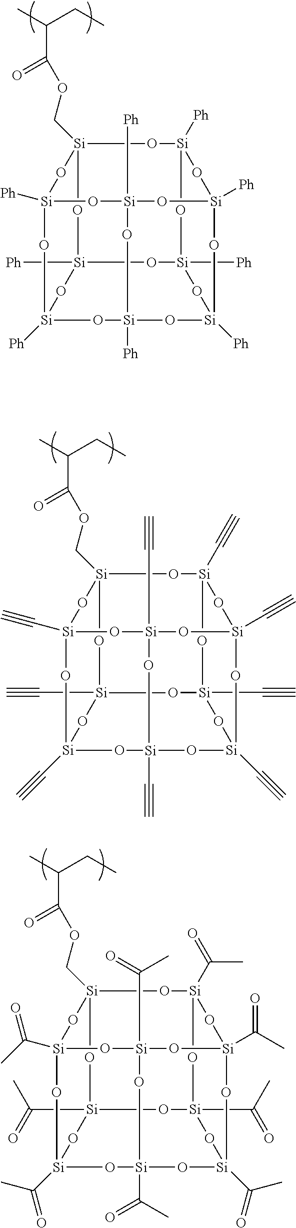

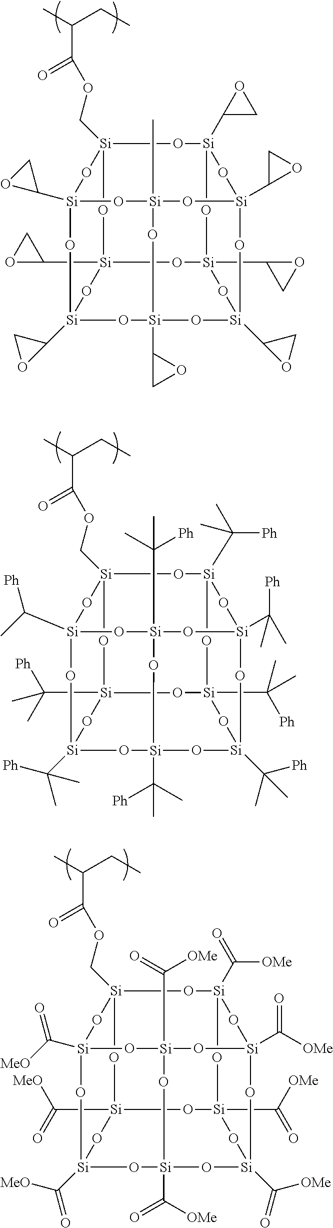

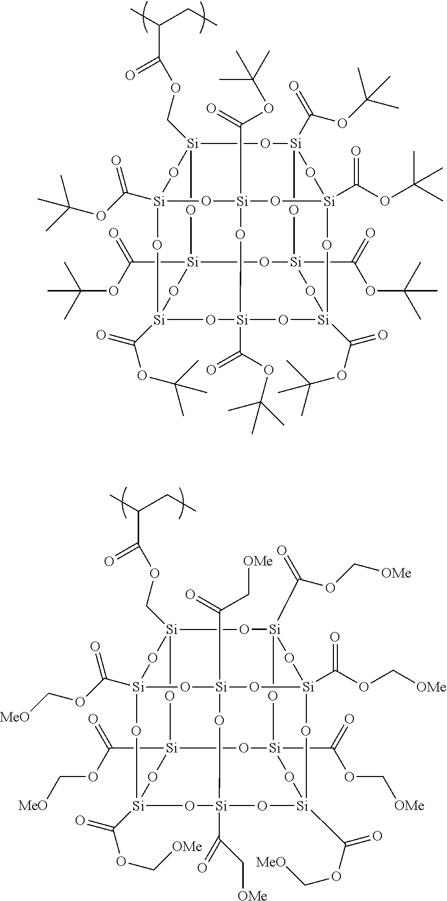

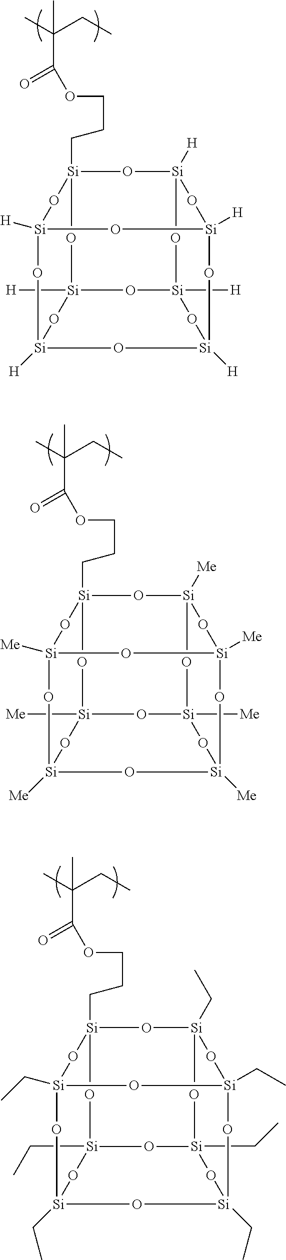

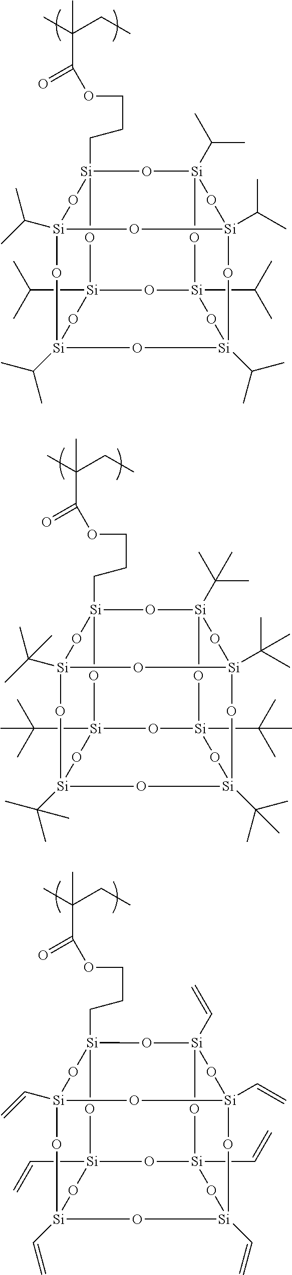

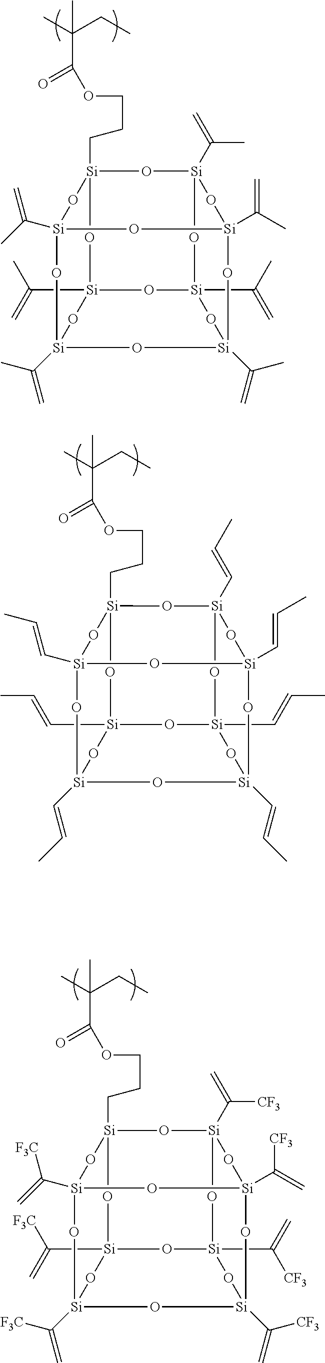

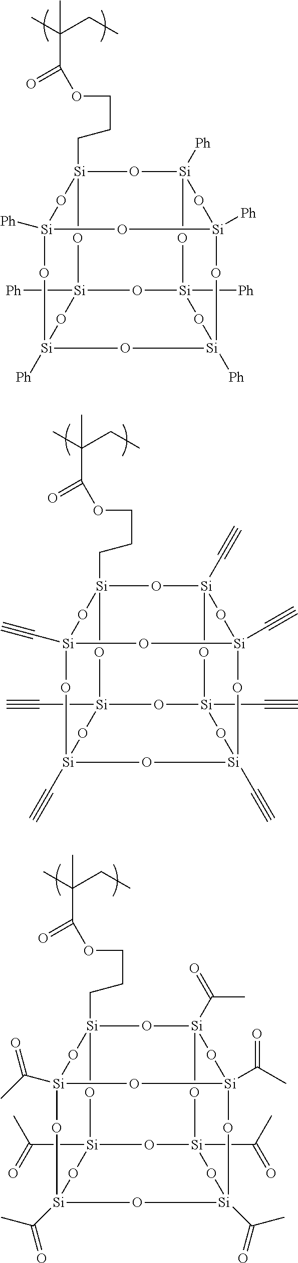

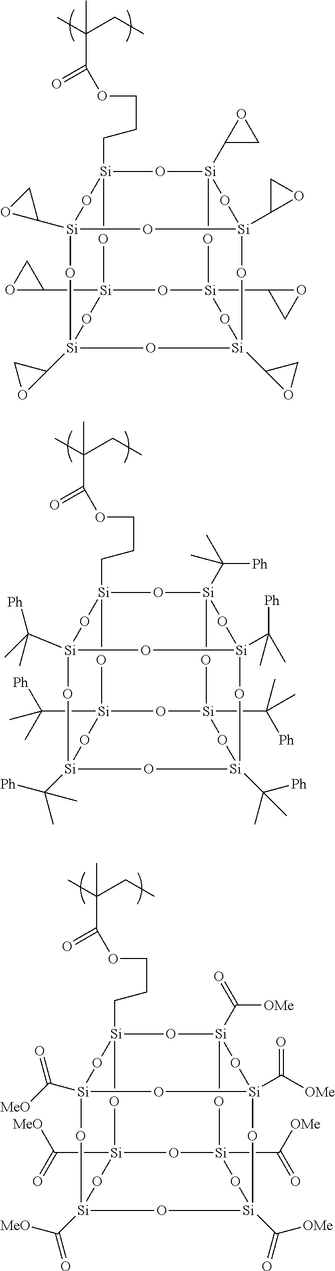

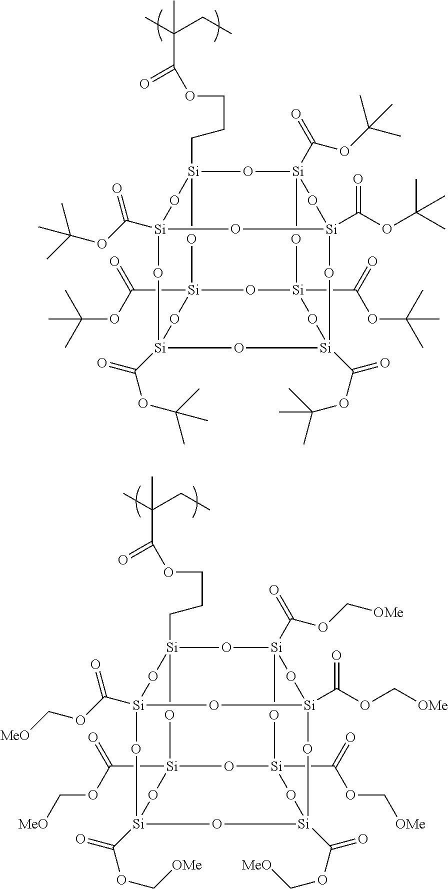

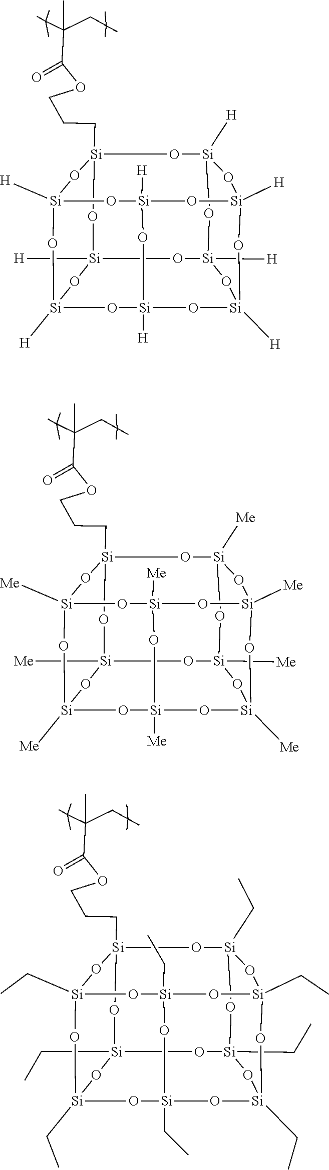

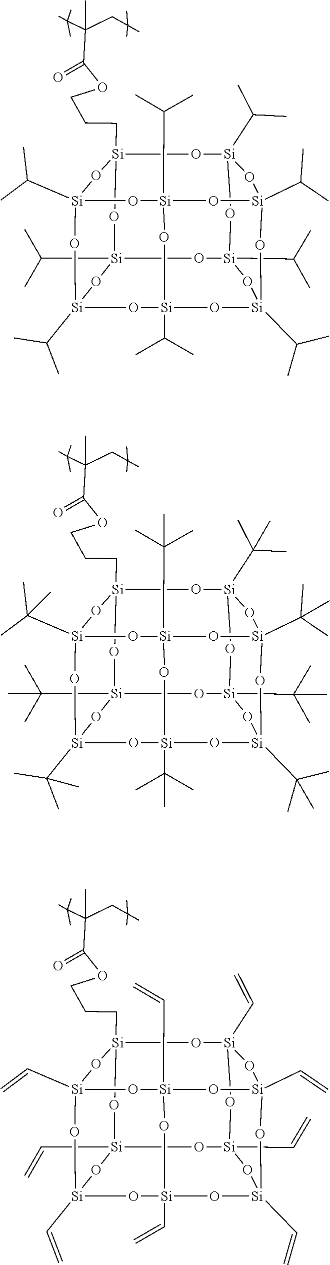

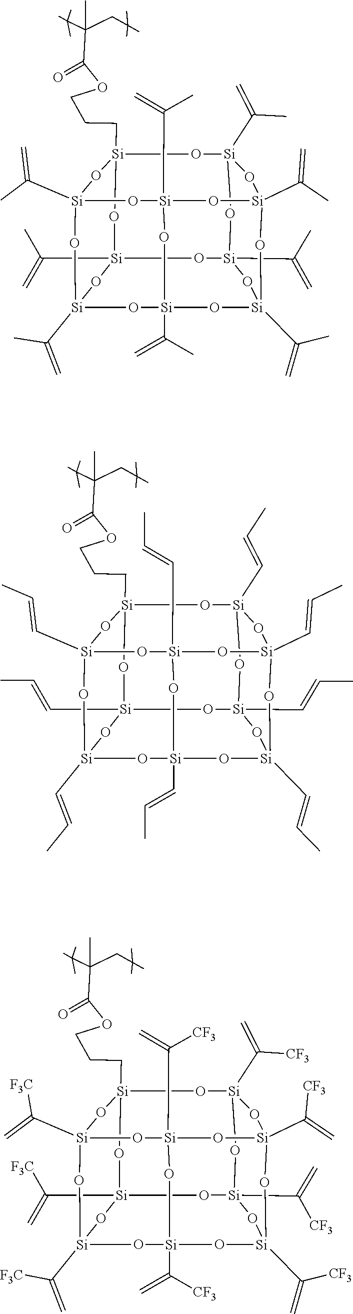

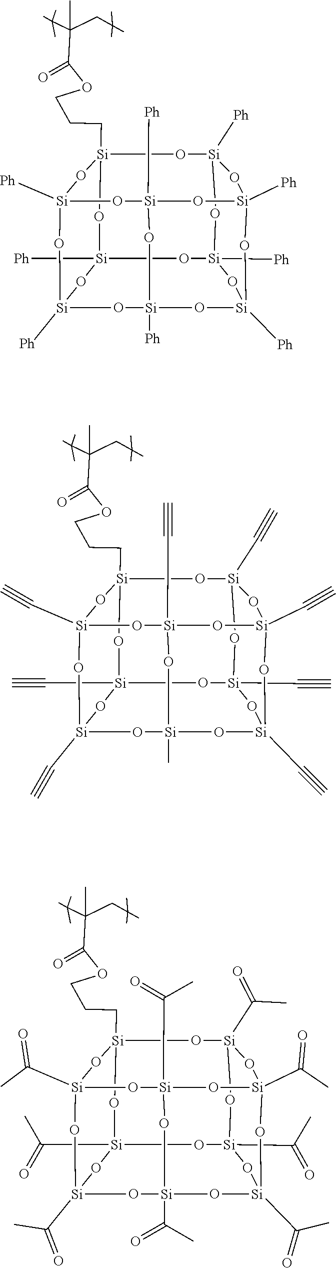

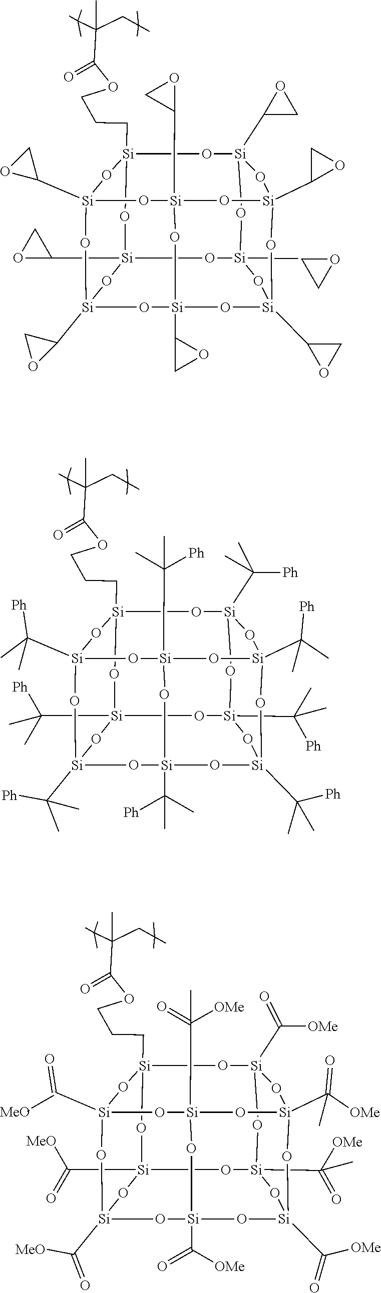

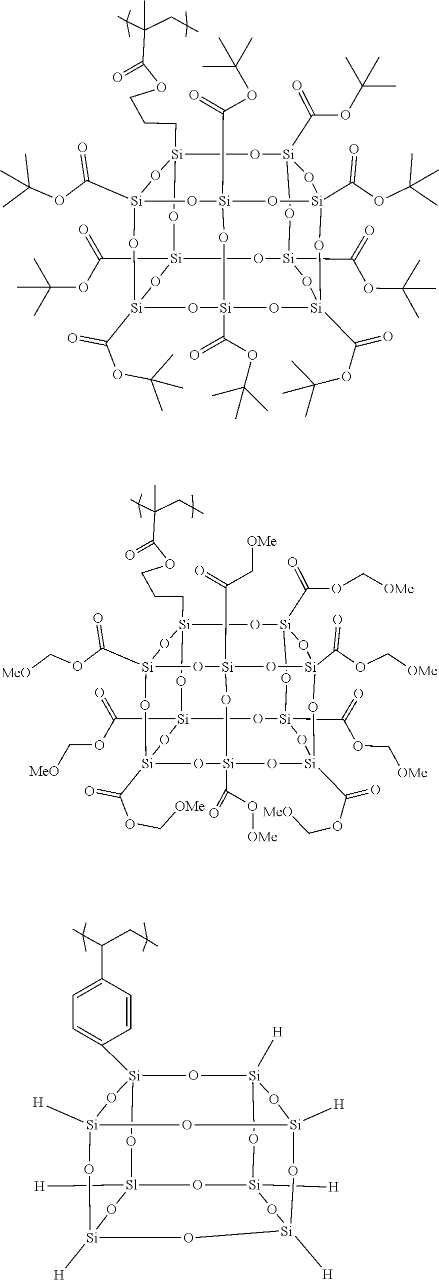

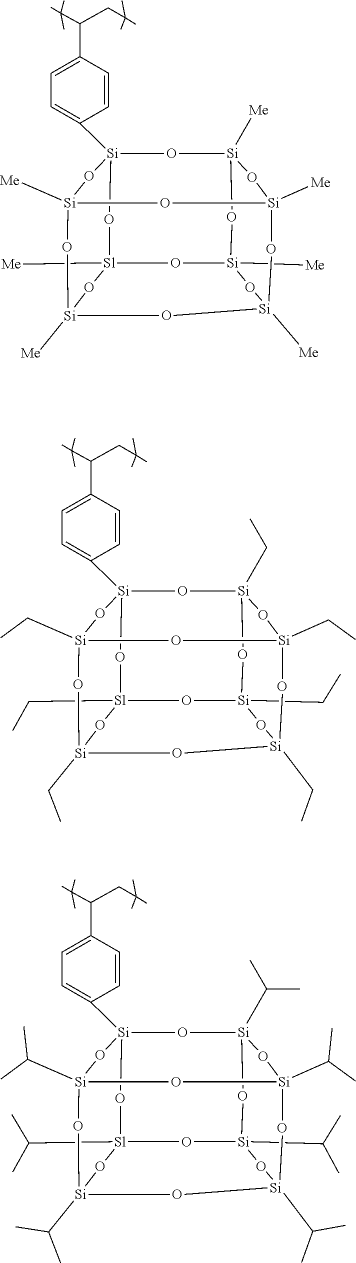

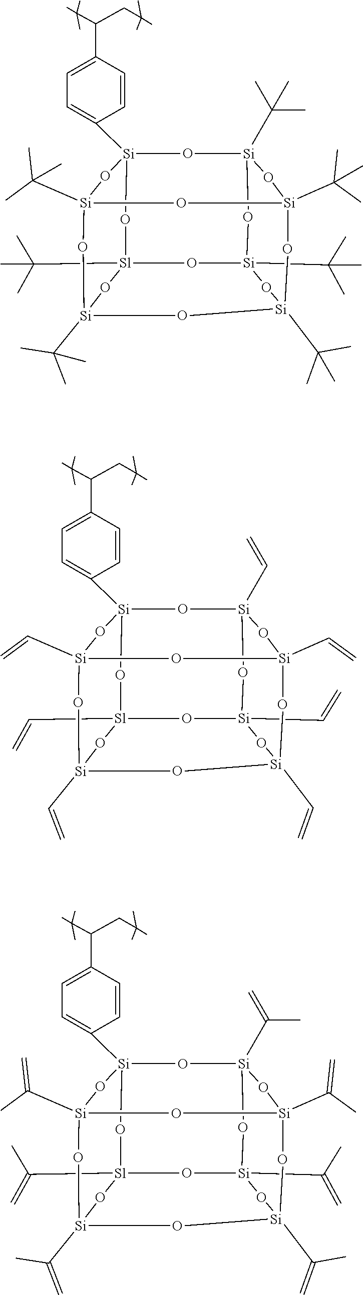

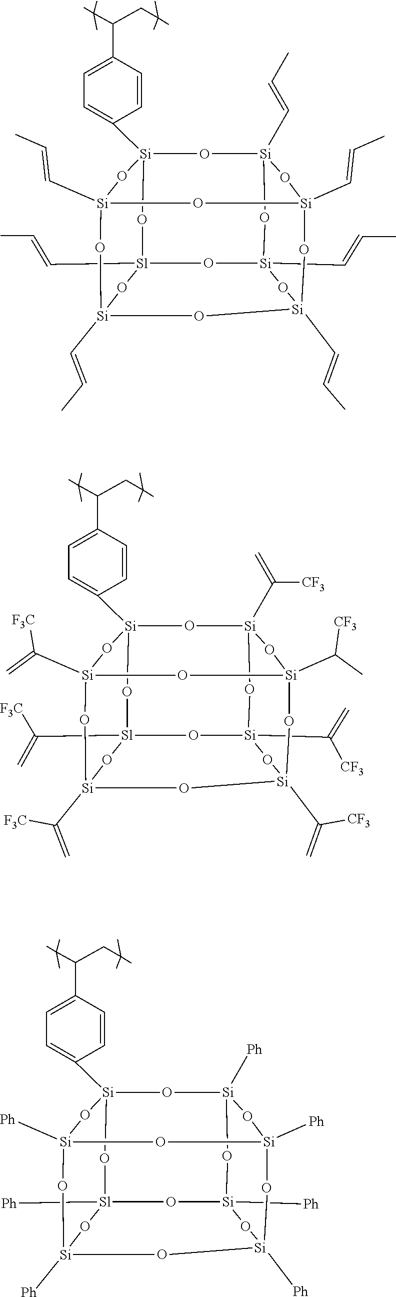

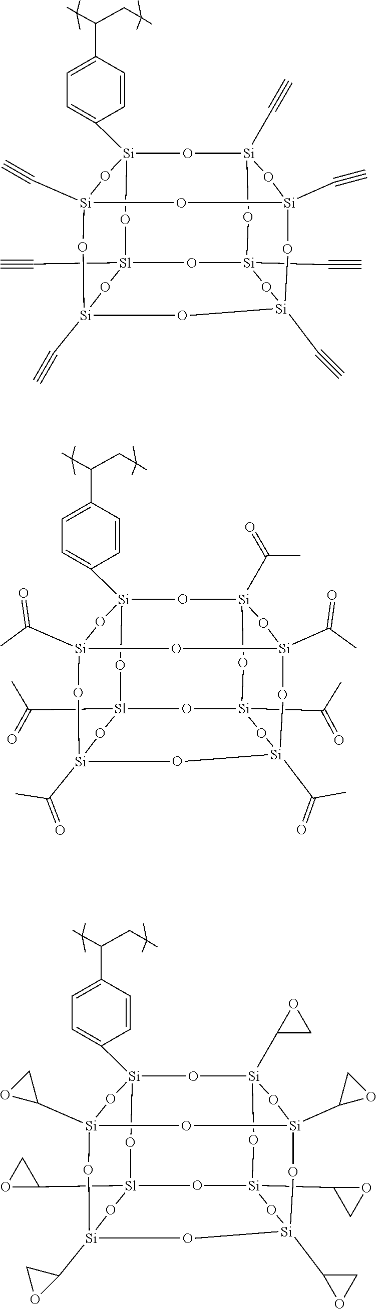

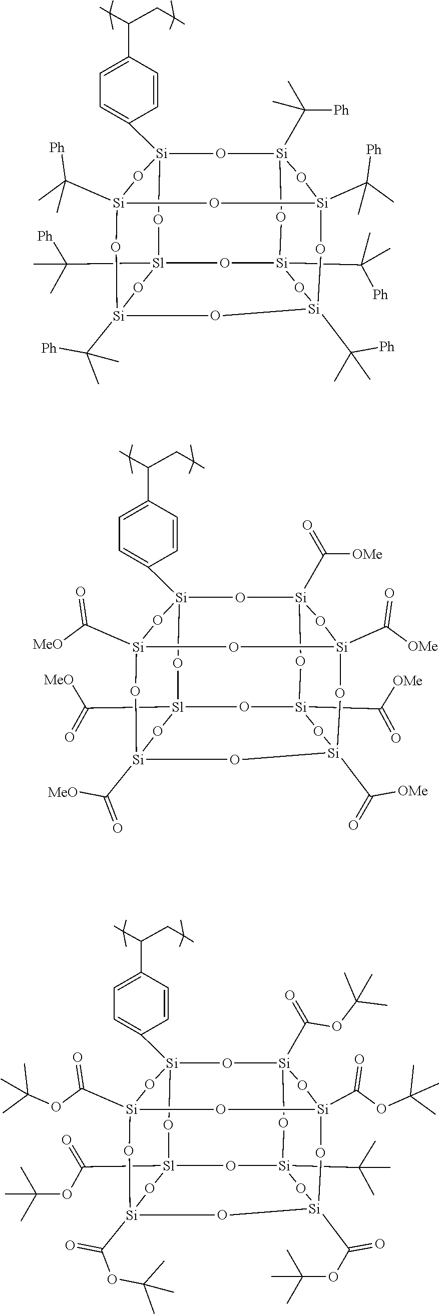

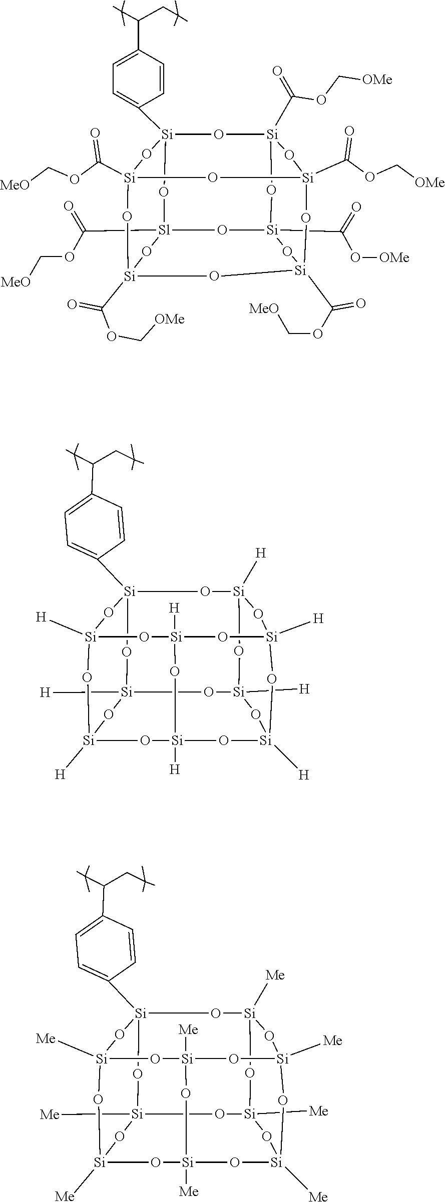

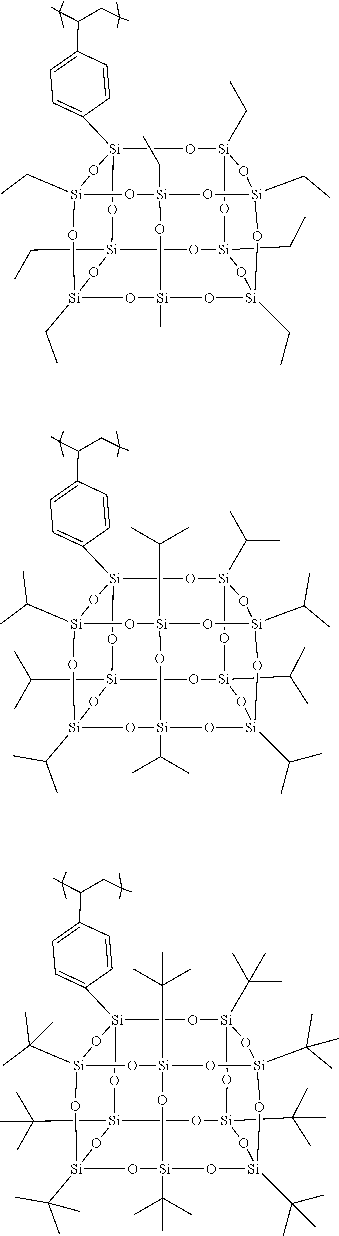

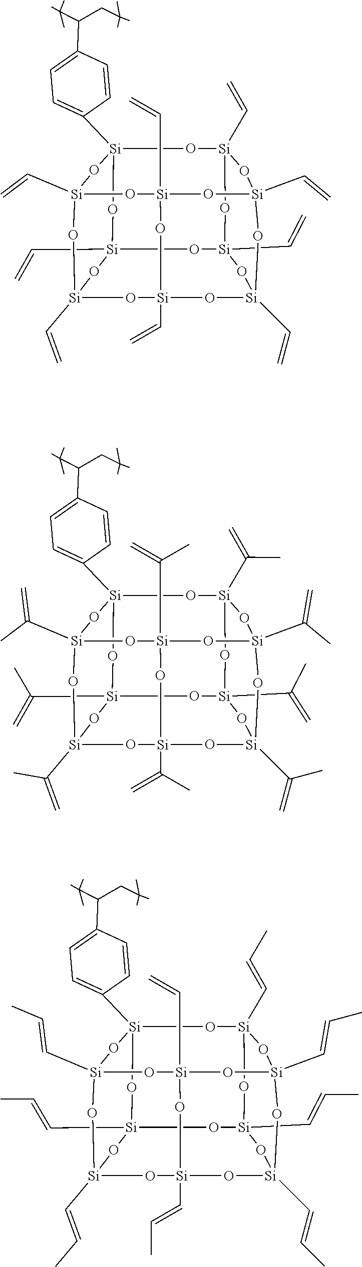

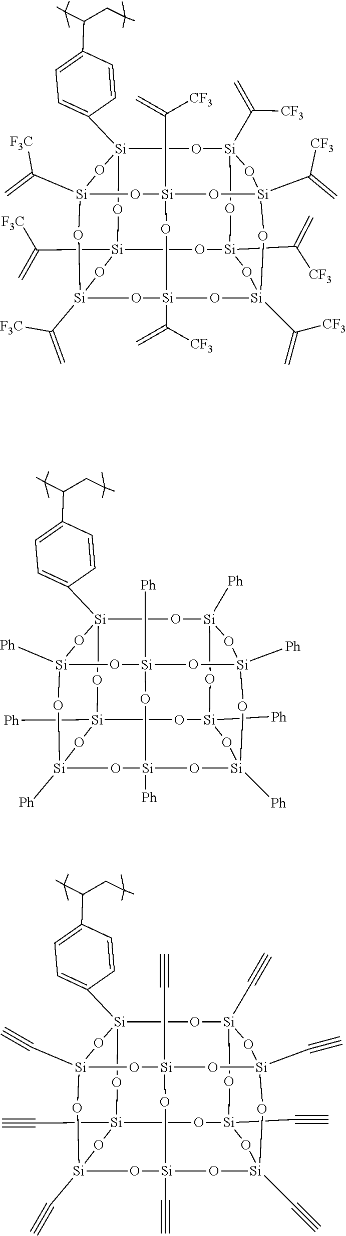

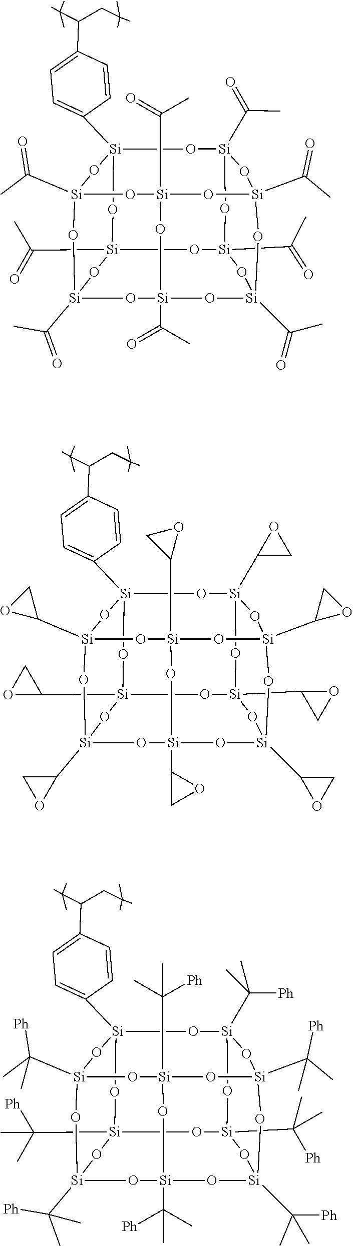

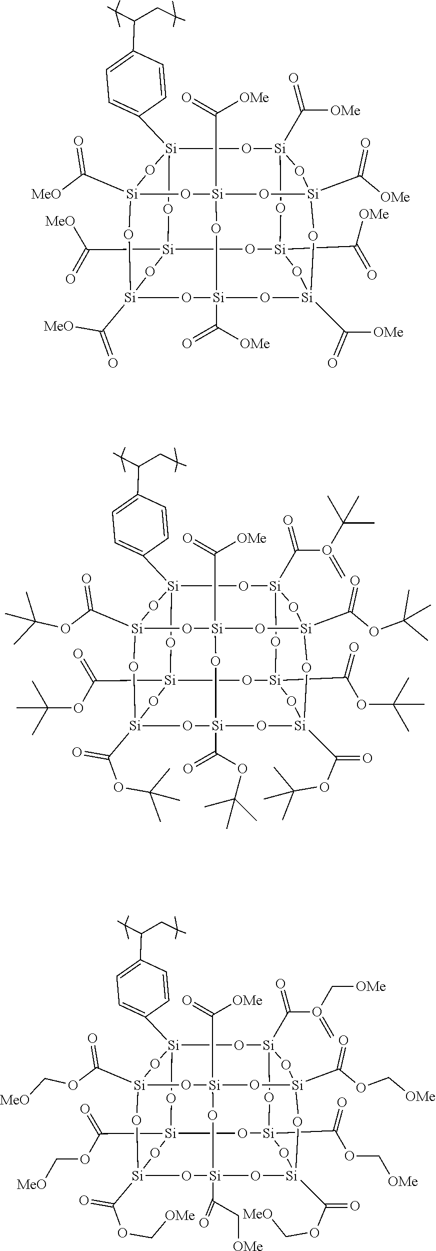

The polymer including the repeating unit represented by the formula (5) may further include a repeating unit other than the repeating unit represented by the formula (5) (hereinafter also referred to as another repeating unit). This another repeating unit is not particularly limited, but may include a repeating unit having an acid-dissociable group, a repeating unit having an adhesive group, a repeating unit having a phenolic hydroxy group, and a repeating unit that functions as the photo-acid generator. Examples of this another repeating unit that can be used include those described in JP 7639675 B and its cited references.

In a polymer including a repeating unit represented by the formula (5), the content ratio (molar ratio) between the repeating unit represented by the formula (5) and another repeating unit is preferably repeating unit represented by formula (5):another repeating unit=10:90 to 90:10, more preferably 15:85 to 85:15, and still more preferably 20:80 to 80:20.

The weight-average molecular weight (Mw) of the polymer including a repeating unit represented by the formula (5) is preferably 1,000 to 500,000, and more preferably 3,000 to 100,000.

The dispersity (Mw/Mn) of a polymer including a repeating unit represented by the formula (5) is preferably a narrow dispersity of 1.00 to 2.00. Mw/Mn is preferably more than 1.30, and the lower limit may be 1.40, 1.50, or 1.60 and the upper limit may be 1.70, 1.80, or 1.90.

Examples of the method for synthesizing a polymer including a repeating unit represented by the formula (5) include a method of heating and polymerizing a monomer that provides the repeating unit described above in an organic solvent with the addition of a radical polymerization initiator.

Specific examples of organic solvents used in polymerization reactions include toluene, benzene, THE, diethyl ether, dioxane, cyclohexane, cyclopentane, cyclopentanone, cyclohexanone, methyl ethyl ketone (MEK), propylene glycol monomethyl ether (PGME), propylene glycol monomethyl ether acetate (PGMEA), and γ-butyrolactone (GBL). Specific examples of the polymerization initiator include 2,2′-azobisisobutyronitrile (AIBN), 2,2′-azobis(2,4-dimethylvaleronitrile), dimethyl-2,2-azobis(2-methylpropionate), 1,1′-azobis(1-acetoxy-1-phenylethane), benzoyl peroxide, and lauroyl peroxide. The amount of the polymerization initiator added is preferably 0.01 to 25 mol % based on the total amount of monomers to be polymerized. The reaction temperature is preferably 50 to 150° C., and more preferably 60 to 100° C. The reaction time is preferably 2 to 24 hours, and from the viewpoint of production efficiency, and more preferably 2 to 12 hours.

The polymerization initiator may be added to the monomer solution and supplied to the reaction vessel, or an initiator solution may be prepared separately from the monomer solution and supplied to the reaction vessel independently. Radicals generated from the initiator during the waiting time may accelerate the polymerization reaction and produce ultra-high molecular weight molecules, and thus from the viewpoint of a quality control, it is preferable to prepare the monomer solution and initiator solution independently and add them dropwise. Further, to adjust the molecular weight, known chain transfer agents such as dodecyl mercaptan and 2-mercaptoethanol may be used in combination. In this case, the amount of the chain transfer agent added is preferably 0.01 to 20 mol % based on the total amount of monomers to be polymerized.

Note that the amount of each monomer in the monomer solution, for example, may be appropriately set so as to achieve the desired content ratio of the repeating units described above.

When the resist composition includes a polymer having a repeating unit represented by the formula (5), a single polymer may be used, or a plurality of polymers with different molecular weights or different n5, L, R⁵, and X⁵ may be used.

The resist composition can include a silsesquioxane precursor represented by the following formula (6):

R⁶¹—Si(X⁶)₃ (6)
wherein R⁶¹ is a hydrogen atom, a hydrocarbyl carbonyl group having 1 to 40 carbon atoms and optionally including a heteroatom, or a hydrocarbyl group having 1 to 40 carbon atoms and optionally including a heteroatom; each R⁶¹ is the same as or different from each other; X⁶ is a hydrogen atom, a halogen atom, or a monovalent organic group represented by —O—R⁶²; R⁶² is a hydrogen atom, a hydrocarbyl carbonyl group having 1 to 40 carbon atoms and optionally including a heteroatom, or a hydrocarbyl group having 1 to 40 carbon atoms and optionally including a heteroatom; and each X⁶ is the same as or different from each other.

In the formula (6), R⁶¹ is a hydrogen atom, a hydrocarbyl carbonyl group having 1 to 40 carbon atoms, preferably 1 to 20 carbon atoms, and optionally including a heteroatom, or a hydrocarbyl group having 1 to 40 carbon atoms, preferably 1 to 20 carbon atoms, and optionally including a heteroatom. The hydrocarbyl group and the hydrocarbyl portion of the hydrocarbyl carbonyl group may be saturated or unsaturated and may be linear, branched, or cyclic. Specific examples thereof include: alkyl groups having 1 to 20 carbon atoms such as a methyl group, an ethyl group, a n-propyl group, an isopropyl group, a n-butyl group, an isobutyl group, a sec-butyl group, a tert-butyl group, a tert-pentyl group, a n-pentyl group, a n-hexyl group, a n-octyl group, a 2-ethylhexyl group, a n-nonyl group, and a n-decyl group; cyclic saturated hydrocarbyl groups having 3 to 10 carbon atoms such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups having 2 to 20 carbon atoms such as a vinyl group and a 2-propenyl group; aryl groups having 6 to 20 carbon atoms such as a phenyl group and a naphthyl group; and groups obtained by combining these. In addition, a part or all of the hydrogen atoms in the hydrocarbyl group may be substituted with a group including a heteroatom such as an oxygen atom, a sulfur atom, a nitrogen atom, and a halogen atom; a part of the —CH₂— in the hydrocarbyl group may be substituted with a group including a heteroatom such as an oxygen atom, a sulfur atom, a nitrogen atom, and a silicon atom; and as a result, a hydroxy group, a siloxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride, and the like may be included.

In the formula (6), X⁶ is a hydrogen atom, a halogen atom, or a monovalent organic group represented by —O—R⁶². Specific examples of halogen atoms include fluorine, chlorine, bromine, iodine, and astatine. R⁶² is a hydrogen atom, a hydrocarbyl carbonyl group having 1 to 40 carbon atoms, preferably 1 to 20 carbon atoms, and optionally including a heteroatom, or a hydrocarbyl group having 1 to 40 carbon atoms, preferably 1 to 20 carbon atoms, and optionally including a heteroatom. The hydrocarbyl group and the hydrocarbyl portion of the hydrocarbyl carbonyl group may be saturated or unsaturated and may be linear, branched, or cyclic. Specific examples thereof include: alkyl groups having 1 to 20 carbon atoms such as a methyl group, an ethyl group, a n-propyl group, an isopropyl group, a n-butyl group, an isobutyl group, a sec-butyl group, a tert-butyl group, a tert-pentyl group, a n-pentyl group, a n-hexyl group, a n-octyl group, a 2-ethylhexyl group, a n-nonyl group, and a n-decyl group; cyclic saturated hydrocarbyl groups having 3 to 10 carbon atoms such as a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a norbornyl group, a tricyclo[5.2.1.0^{2,6}]decanyl group, an adamantyl group, and an adamantylmethyl group; alkenyl groups having 2 to 20 carbon atoms such as a vinyl group and a 2-propenyl group; aryl groups having 6 to 20 carbon atoms such as a phenyl group and a naphthyl group; and groups obtained by combining these. In addition, a part or all of the hydrogen atoms in the hydrocarbyl group may be substituted with a group including a heteroatom such as an oxygen atom, a sulfur atom, a nitrogen atom, and a halogen atom; a part of the —CH₂— in the hydrocarbyl group may be substituted with a group including a heteroatom such as an oxygen atom, a sulfur atom, a nitrogen atom, and a silicon atom; and as a result, a hydroxy group, a siloxy group, a cyano group, a halogen atom, a carbonyl group, an ether bond, a thioether bond, an ester bond, a sulfonate ester bond, a carbonate bond, a carbamate bond, a lactone ring, a sultone ring, a carboxylic acid anhydride, and the like may be included. In the formula, each X⁶ is the same as or different from each other. In addition, when there is a plurality of monovalent organic groups represented by —O—R⁶², each R⁶² is the same as or different from each other.

Specific examples of the silsesquioxane precursors represented by the formula (6) include, but are not limited to, those shown below. Note that in the following formula, Me is a methyl group.

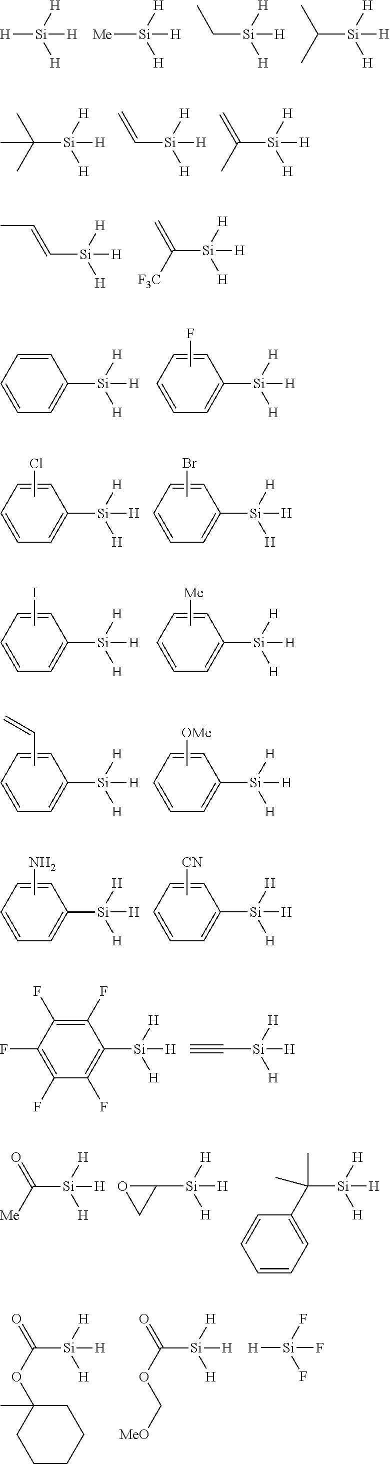

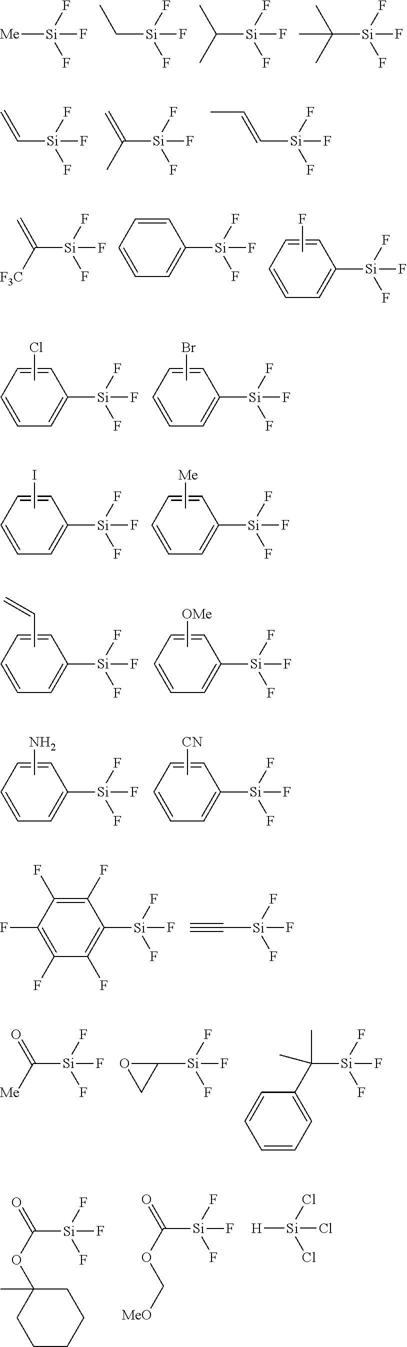

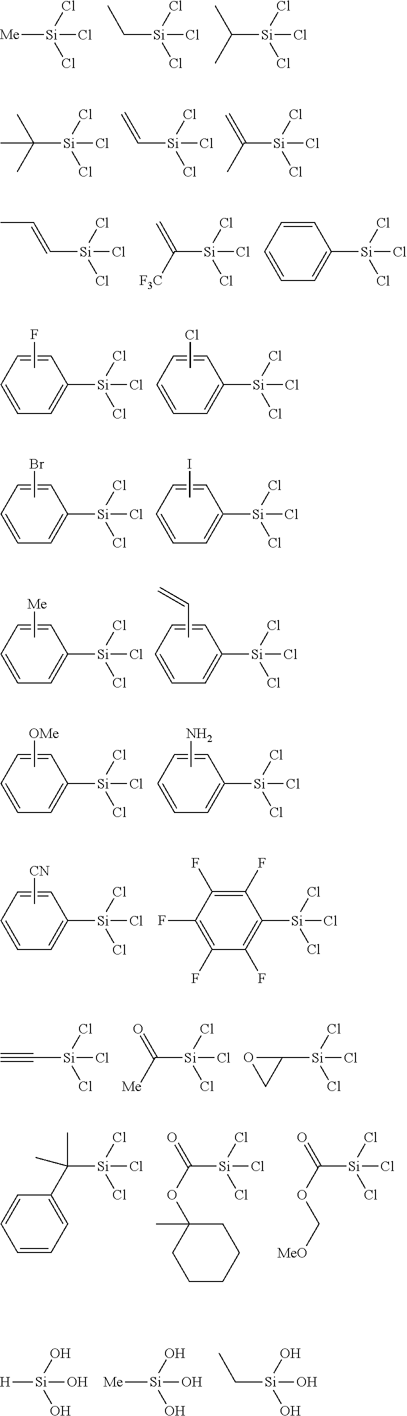

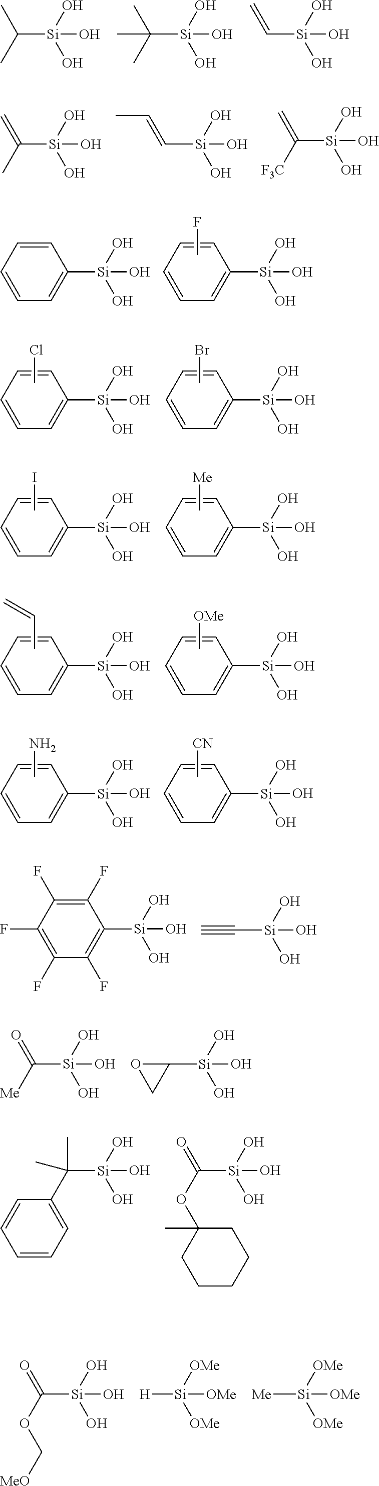

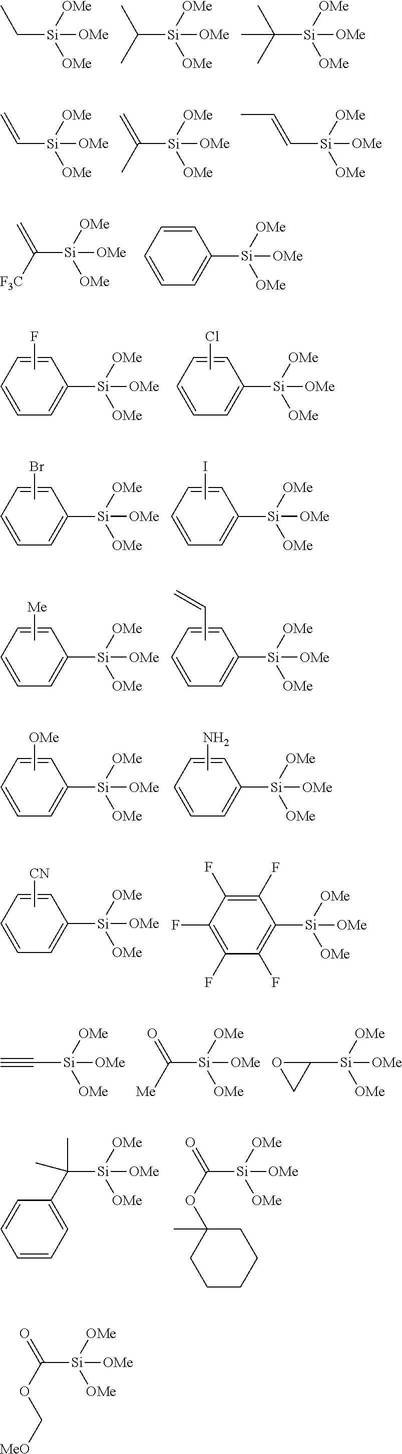

When the resist composition includes a silsesquioxane precursor represented by the formula (6), a single precursor may be used, or a plurality of precursors with different R⁶¹ and X⁶ may be used.

When the resist composition includes the silsesquioxane precursor represented by the formula (6), the resist composition may include an oxygen crosslinking agent in addition to the silsesquioxane precursor. Examples of the oxygen crosslinking agents include water, alcohol, ether, ester, carboxylic acid, epoxide, amine oxide, ketone, and aldehyde. It is preferable to use water or alcohol as the oxygen crosslinking agent.

When the resist composition includes the silsesquioxane precursor represented by the formula (6), a condensation reaction occurs with water in the environment, oxygen, the solvent, or the oxygen crosslinking agent during film formation, converting the precursor into a silsesquioxane compound.

The resist composition may include only one type of silsesquioxane compound or silsesquioxane precursor represented by formulae (1) to (6), or may include a plurality of types. In addition, the content of the silsesquioxane compound or silsesquioxane precursor in the resist composition used in the present invention is preferably 10 to 100 mass %, more preferably 50 to 100 mass %, and still more preferably 90 to 100 mass % based on the total solid content. In addition, when the resist composition used in the present invention includes an organic solvent as described below, the total solid content is preferably 0.1 to 10 mass % and more preferably 1 to 5 mass % based on the total amount of the resist composition.

### [Organic Solvent]

The resist composition used in the present invention preferably includes an organic solvent. The organic solvent is not particularly limited, as long as it can dissolve the silsesquioxane compound or silsesquioxane precursor and form a film. Examples of such organic solvents include: ketones such as cyclohexanone and methyl 2-n-pentyl ketone; alcohols such as 3-methoxybutanol, 3-methyl-3-methoxybutanol, 1-methoxy-2-propanol, 1-ethoxy-2-propanol, and diacetone alcohol; ethers such as propylene glycol monomethyl ether, ethylene glycol monomethyl ether, propylene glycol monoethyl ether, ethylene glycol monoethyl ether, propylene glycol dimethyl ether, and diethylene glycol dimethyl ether; esters such as propylene glycol monomethyl ether acetate (PGMEA), propylene glycol monoethyl ether acetate, ethyl lactate, ethyl pyruvate, butyl acetate, methyl 3-methoxypropionate, ethyl 3-ethoxypropionate, methyl 2-hydroxyisobutyrate, tert-butyl acetate, cyclohexyl acetate, tert-butyl propionate, and propylene glycol monotert-butyl ether acetate; lactones such as γ-butyrolactone; carboxylic acids such as acetic acid and propionic acid; aromatics such as toluene, xylene, cresol, anisole, and benztrifluoride; halogenated hydrocarbons such as dichloromethane, chloroform, and carbon tetrachloride; and mixed solvents thereof.

The content of the organic solvent is preferably 200 to 20,000 parts by mass, and more preferably 500 to 15,000 parts by mass, based on 100 parts by mass of the silsesquioxane compound or silsesquioxane precursor.

It is presumed that the resist composition used in the present invention exhibits contrast by changing the development resistance of exposed and unexposed portions due to photodecomposition of the silsesquioxane as the main component, and subsequent aggregation or crosslinking reactions between the partially destroyed silsesquioxanes. This reaction is not catalytic, and thus the resist composition used in the present invention functions as a non-chemically amplified resist composition. As a result, it is possible to achieve resolution even in fine regions where pattern formation is difficult with conventional chemically amplified resist compositions containing multi-component polymers as a main component. In particular, for BEUV lithography, the silicon atoms in the silsesquioxane compound have high BEUV absorption ability, resulting in a resist composition with improved stochastics and excellent sensitivity and LWR. In addition, the silsesquioxane compound or silsesquioxane precursor converges into a thermally stable structure, and thus also has excellent storage stability. In addition, there is no significant change in performance over time after PEB.

### [Photo-Acid Generator]

The resist composition used in the present invention may include a photo-acid generator as the other component in addition to the silsesquioxane compound or silsesquioxane precursor. The use of a photo-acid generator generates acid in exposed portions, which can be expected to promote the crosslinking reaction of the silsesquioxane. Such a photo-acid generator is not particularly limited as long as it generates acid upon exposure to high-energy rays, and conventional photo-acid generators known as photo-acid generators for chemically amplified resist compositions can be used, and photo-acid generators that generate sulfonic acid, imide acid, or methide acid are particularly preferable. Examples of suitable photo-acid generators include a sulfonium salt, an iodonium salt, sulfonyldiazomethane, N-sulfonyloxyimide, and oxime-O-sulfonate-type acid generators. Specific examples of the photo-acid generator include those described in paragraphs [0122] to [0142] of JP 2008-111103 A and those described in paragraphs [0127] to [0193] of JP 2022-163697 A.

When the resist composition used in the present invention includes the photo-acid generator, the content thereof is preferably 0.01 to 20 mass % based on the total solid content. Note that in the present invention, the term “solid content” refers collectively to all components of the resist composition excluding the solvent. The photo-acid generator may be used singly, or may be used in combination of two or more.

### [Quencher]

The resist composition used in the present invention may include a quencher as the other components. Examples of the quencher include conventional basic compounds. Examples of the conventional basic compound include primary, secondary, or tertiary aliphatic amines, mixed amines, aromatic amines, heterocyclic amines, nitrogen-containing compounds having a carboxy group, nitrogen-containing compounds having a sulfonyl group, nitrogen-containing compounds having a hydroxy group, nitrogen-containing compounds having a hydroxyphenyl group, alcoholic nitrogen-containing compounds, amides, imides, and carbamates. In particular, primary, secondary, and tertiary amine compounds described in paragraphs [0146] to [0164] of JP 2008-111103 A, particularly amine compounds having a hydroxy group, an ether bond, an ester bond, a lactone ring, a cyano group, or a sulfonate ester bond, compounds having a carbamate group described in JP 3790649 B, or the like are preferable. Adding such a basic compound can, for example, further suppress the diffusion rate of the acid in the resist film or correct the shape.

In addition, examples of the quencher include an onium salt, such as a sulfonium salt, an iodonium salt, and an ammonium salt, of a sulfonic acid and a carboxylic acid not fluorinated at the α-position, as described in JP 2008-158339 A. Sulfonic acids, imido acids, or methide acids fluorinated at the α-position are necessary to deprotect the acid-labile groups of carboxylic acid esters, but salt exchange with onium salts that are not fluorinated at the α-position releases sulfonic acids or carboxylic acids that are not fluorinated at the α-position. Sulfonic acids and carboxylic acids that are not fluorinated at the α-position do not undergo deprotection reactions and thus function as quenchers.

Further examples of the quencher include the polymer-type quencher described in JP 2008-239918 A. This quencher enhances the rectangularity of resist patterns by orienting at the surface of the resist film.

When the resist composition used in the present invention includes the quencher, the content thereof is preferably 0.01 to 20 mass % based on the total solids. The quencher may be used singly, or may be used in combination of two or more.

### [Radical Scavenger]

The resist composition used in the present invention may include a radical scavenger as another component. Adding a radical scavenger can control the photoreaction during photolithography and adjust sensitivity.

Hindered phenols, quinones, hindered amines, thiol compounds, and the like can be used as the radical scavenger. Specific examples of hindered phenols include dibutylhydroxytoluene and 2,2′-methylenebis(4-methyl-6-tert-butylphenol). Specific examples of quinones include 4-methoxyphenol (methoquinone) and hydroquinone. Specific examples of hindered amines include 2,2,6,6-tetramethylpiperidine and 2,2,6,6-tetramethylpiperidine-N-oxy radical. Specific examples of thiols include dodecanethiol and hexadecanethiol.

When the resist composition used in the present invention includes the radical scavenger, the content thereof is preferably 0.01 to 10 mass % based on the total solids. The radical scavenger may be used singly, or may be used in combination of two or more.

### [Crosslinking Agent]

The resist composition used in the present invention may include a crosslinking agent. Adding a crosslinking agent can promote photoreaction during photolithography and increase the sensitivity of the resist.

Examples of the crosslinking agent include compounds containing double bonds, such as epoxy compounds, melamine compounds, guanamine compounds, glycoluril compounds or urea compounds, isocyanate compounds, azide compounds, and alkenyloxy groups, substituted with at least one group selected from methylol groups, alkoxymethyl groups, and acyloxymethyl groups. In addition, the compounds having an oxygen-containing functional group such as a hydroxy group, an ether bond, an ester bonds, a carboxylic acid, an amine oxide group, a ketone group, and an aldehyde group can be used as crosslinking agents.

Examples of the epoxy compounds include tris(2,3-epoxypropyl)isocyanurate, trimethylolmethane triglycidyl ether, trimethylolpropane triglycidyl ether, and triethylolethane triglycidyl ether.

Examples of the melamine compounds include compounds in which 1 to 6 methylol groups of hexamethylol melamine, hexamethoxymethyl melamine, and hexamethylol melamine are methoxymethylated or mixtures thereof, and compounds in which 1 to 6 methylol groups of hexamethoxyethyl melamine, hexaacyloxymethyl melamine, and hexamethylol melamine are acyloxymethylated or mixtures thereof.

Examples of guanamine compounds include compounds in which 1 to 4 methylol groups of tetramethylolguanamine, tetramethoxymethylguanamine, and tetramethylolguanamine are methoxymethylated or mixtures thereof, and compounds in which 1 to 4 methylol groups of tetramethoxyethylguanamine, tetraacyloxyguanamine, tetramethylolguanamine are acyloxymethylated or mixtures thereof.

Examples of glycoluril compounds include compounds in which 1 to 4 methylol groups of tetramethylol glycoluril, tetramethoxy glycoluril, tetramethoxymethyl glycoluril, and tetramethylol glycoluril are methoxymethylated or mixtures thereof, and compounds in which 1 to 4 methylol groups of tetramethylol glycoluril are acyloxymethylated or mixtures thereof. Examples of urea compounds include compounds in which 1 to 4 methylol groups of tetramethylol urea, tetramethoxymethyl urea, and tetramethylol urea are methoxymethylated or mixtures thereof, and tetramethoxyethyl urea.

Examples of isocyanate compounds include tolylene diisocyanate, diphenylmethane diisocyanate, hexamethylene diisocyanate, and cyclohexane diisocyanate.

Examples of azide compounds include 1,1′-biphenyl-4,4′-bisazide, 4,4′-methylidenebisazide, and 4,4′-oxybisazide.

Examples of compounds containing an alkenyloxy group include ethylene glycol divinyl ether, triethylene glycol divinyl ether, 1,2-propanediol divinyl ether, 1,4-butanediol divinyl ether, tetramethylene glycol divinyl ether, neopentyl glycol divinyl ether, trimethylolpropane trivinyl ether, hexanediol divinyl ether, 1,4-cyclohexanediol divinyl ether, pentaerythritol trivinyl ether, pentaerythritol tetravinyl ether, sorbitol tetravinyl ether, sorbitol pentavinyl ether, and trimethylolpropane trivinyl ether.

Examples of compounds having a hydroxy group include water, and an alkyl alcohol and a phenol, each optionally having a substituent. Examples of compounds having an ether bond include a dialkyl ether, an alkylaryl ether, and a diaryl ether, each optionally having a substituent. Examples of compounds having an ester bond include a carboxylic acid ester, a phosphate ester, and a sulfonic acid ester, each optionally having a substituent. Examples of compounds having a carboxylic acid include an alkylcarboxylic acid and a benzoic acid, each optionally having a substituent. Examples of compounds having an amine oxide group include a tertiary amine oxide and a pyridine N-oxide, each optionally having a substituent. Examples of compounds having a ketone group include a dialkyl ketone, an alkylaryl ketone, and a diaryl ketone, each optionally having a substituent. Examples of compounds having an aldehyde group include an alkylaldehyde and an arylaldehyde, each optionally having a substituent. The compound having an oxygen-containing functional group may have only one of the above functional groups, or may have a plurality of functional groups. The number of the above functional groups included in the compound having an oxygen-containing functional group is preferably 1 or more and 10 or less.

When the resist composition used in the present invention includes the crosslinking agent, the content thereof is preferably 0.01 to 50 mass % based on the total solid content. The crosslinking agent may be used singly, or may be used in combination of two or more.

### [Surfactant]

The resist composition used in the present invention may include a surfactant as another component. Examples of the surfactant include those described in JP 2010-215608 A and JP 2011-16746 A. Among these, FC-4430 (manufactured by 3M Company, Surflon (registered trademark) S-381 (manufactured by AGC SEIMI CHEMICAL CO., LTD.), Olfine (registered trademark) E1004 (manufactured by Nissin Chemical Industry Co., Ltd.), KH-20, KH-30 (manufactured by AGC SEIMI CHEMICAL CO., LTD.), and oxetane ring-opening polymers represented by the following formula (surf-1) are preferable.

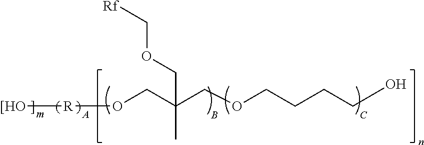

In the formula (surf-1), R is a divalent to tetravalent aliphatic group having 2 to 5 carbon atoms. Examples of the divalent aliphatic group include ethylene groups, 1,4-butylene groups, 1,2-propylene groups, 2,2-dimethyl-1,3-propylene groups, and 1,5-pentylene groups, while trivalent or tetravalent groups include the followings:

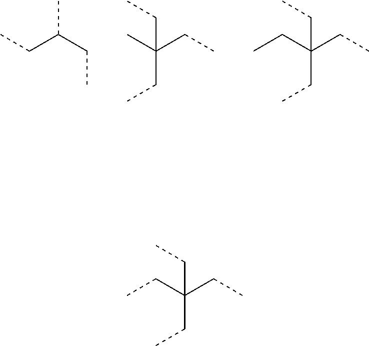

wherein the broken lines are an attachment point and are partial structures derived from glycerol, trimethylolethane, trimethylolpropane, and pentaerythritol, respectively.

Among these, 1,4-butylene groups, 2,2-dimethyl-1,3-propylene groups and the like are preferable.

Rf is a trifluoromethyl group or a pentafluoroethyl group, preferably a trifluoromethyl group. “m” is an integer of 0 to 3, “n” is an integer of 1 to 4, and the sum of n and m is the valence of R, which is an integer of 2 to 4. A is 1. B is an integer of 2 to 25, preferably an integer of 4 to 20. C is an integer of 0 to 10, preferably 0 or 1. The structural units in the formula (surf-1) are not restricted in their order, and may be bonded in blocks or randomly. Details on the production of partially fluorinated oxetane ring-opening polymer surfactants are available in U.S. Pat. No. 5,650,483 A and the like.

When the resist composition used in the present invention includes the surfactant, the content thereof is preferably 0.001 to 20 parts by mass, and more preferably 0.1 to 10 parts by mass, based 100 parts by mass of the silsesquioxane compound or silsesquioxane precursor. The surfactant may be used singly, or may be used in combination of two or more.

### [Patterning Process]

The patterning process of the present invention includes the steps of: (1) forming a resist film on a substrate or on an underlayer film stacked on a substrate; (2) exposing the resist film to BEUV light having a wavelength of 2 to 10 nm; and (3) developing the exposed resist film to form a resist pattern.

### [Step (1)]

The step (1) is a step of forming a resist film on a substrate or on an underlayer film stacked on a substrate. The step (1) can be performed, for example, as follows.

First, a resist film is formed on a substrate for integrated circuit production, or on a resist underlayer film stacked on a substrate (Si, SiO₂, SiN, SiON, TiN, WSi, BPSG, SOG, organic anti-reflection film, and the like), or on a substrate for mask circuit production, or on a resist underlayer film stacked on a substrate (Cr, Cro, CrON, MoSi₂, SiO₂, and the like).

The film formation method may use CVD or ALD, or may use an application method using the resist composition used in the present invention.

When a resist film is formed using ALD, the film formation conditions are not particularly limited, but the vapor-deposition temperature is preferably 50° C. to 600° C. and the vapor-deposition pressure is preferably 100 to 6000 mTorr. In addition, the flow rate of the silsesquioxane precursor is preferably 0.01 to 10 ccm, and the flow rate of the other gases is preferably 100 to 10,000 sccm. The plasma power used in ALD is preferably 200 to 1,000 W based on 300 mm wafer station, using high-frequency plasma (for example, 13.56 MHz, 27.1 MHz, or higher frequency).

When a resist film is formed using CVD, the film formation conditions are not particularly limited, but the vapor-deposition temperature is preferably 250° C. to 350° C., and the reactor pressure is preferably less than 6 Torr. In addition, the flow rate of the silsesquioxane precursor is preferably 100 to 500 ccm, and the flow rate of the other gases is preferably 1,000 to 2,000 sccm. The plasma power used in CVD is preferably 200 W to 1,000 W based on 300 mm wafer station, using high-frequency plasma (for example, 13.56 MHz or more).

As the application method, for example, the application is performed so as to make the coating film thickness become 0.01 to 2 μm by a suitable application method such as spin coating, roll coating, flow coating, dip coating, spray coating, and doctor coating. The coating film obtained by the application method may be pre-baked, for example, on a hot plate, preferably at 60 to 200° C. for 10 seconds to 30 minutes, and more preferably at 80 to 180° C. for 30 seconds to 20 minutes, to form a resist film. The resist film thickness is not particularly limited, but the film is formed so as to have a film thickness of 0.01 to 2 μm.

Note that the resist underlayer film refers to a film formed between the substrate and the resist film in a multilayer resist process, and the resist underlayer film is not particularly limited, and conventionally known film can be used.

### [Step (2)]

The step (2) is a step of exposing the resist film to BEUV light having a wavelength of 2 to 10 nm. The step (2) can be performed, for example, as follows.

Then, the resist film is exposed to BEUV light. In the present invention, BEUV light refers to light with a peak wavelength of 2 to 10 nm. Specific examples of light sources for the BEUV light include excimer lasers, synchrotron radiation, and free electron lasers. The peak wavelength of the BEUV light used is preferably 2 to 10 nm, more preferably 2 to 8 nm, still more preferably 2 to 7 nm, further more preferably 2 to 6.8 nm, and particularly preferably 6.6 to 6.8 nm. In a case of irradiation with BEUV light, the light irradiation is performed directly or using a mask to form the desired pattern, with an exposure dose preferably of about 1 to 300 mJ/cm², and more preferably about 10 to 200 mJ/cm².

The resist film used in the present invention has strong absorption for BEUV light having a wavelength of 2 to 10 nm, and particularly for BEUV light having a wavelength of 6.6 to 6.8 nm, and thus using this patterning process makes it possible to form patterns with extremely high sensitivity, high resolution performance, and reduced roughness.

Post-exposure baking (PEB) may be performed to accelerate or complete the reaction after photodecomposition. When PEB is performed, PEB is preferably performed on a hot plate or in an oven after exposure, preferably in condition of 30 to 200° C. for 10 seconds to 30 minutes, and more preferably in condition of 60 to 180° C. for 30 seconds to 20 minutes.

### [Step (3)]

The step (3) is a step of developing the exposed resist film to form a resist pattern. The step (3) can be performed, for example, as follows.

The development method performed after exposure or PEB can be either wet development or dry development. For wet development, alkaline development or organic solvent development can be used, and organic solvent development is preferable when a pattern is formed using the resist composition used in the present invention. Wet development is performed on the exposed resist film by a conventional method such as a dip method, a puddle method, or a spray method, preferably for 3 seconds to 3 minutes, and more preferably 5 seconds to 2 minutes, to form a desired pattern.

The resist composition used in the present invention exhibits a difference in solubility between exposed and unexposed portions upon exposure, allowing the formation of positive or negative patterns. For this reason, it is possible to use a developer or dry developing gas that removes exposed portions but not unexposed portions, or a developer or dry developing gas that removes unexposed portions but not exposed portions. As described above, the patterning process of the present invention can form positive or negative patterns by appropriately selecting a developer or dry developing gas, making it widely applicable to the formation of a variety of fine patterns.

Examples of the organic solvent used as a developer include 2-octanone, 2-nonanone, 2-heptanone, 3-heptanone, 4-heptanone, 2-hexanone, 3-hexanone, diisobutyl ketone, methylcyclohexanone, acetophenone, methylacetophenone, propyl acetate, butyl acetate, isobutyl acetate, pentyl acetate, butenyl acetate, isopentyl acetate, propyl formate, cyclohexyl acetate, butyl formate, isobutyl formate, pentyl formate, isopentyl formate, methyl valerate, methyl pentenoate, methyl crotonate, ethyl crotonate, methyl propionate, ethyl propionate, ethyl 3-ethoxypropionate, methyl lactate, ethyl lactate, propyl lactate, butyl lactate, isobutyl lactate, pentyl lactate, isopentyl lactate, methyl 2-hydroxyisobutyrate, ethyl 2-hydroxyisobutyrate, methyl benzoate, ethyl benzoate, phenyl acetate, benzyl acetate, methyl phenylacetate, ethyl phenylacetate, benzyl formate, phenylethyl formate, methyl 3-phenylpropionate, benzyl propionate, 2-phenylethyl acetate, dichloromethane, chloroform, carbon tetrachloride, formic acid, acetic acid, and propionic acid. These organic solvents may be used singly, or may be used in combination of two or more.

After development, rinse is performed as needed. A preferred rinse solution is a solvent that is miscible with the developer but do not dissolve the resist film. Examples of the solvent that can be used include an alcohol having 3 to 10 carbon atoms, an ether compound having 8 to 12 carbon atoms, an alkane, alkene, alkyne, and aromatic solvent, each having 6 to 12 carbon atoms.

Specific examples of the alcohol having 3 to 10 carbon atoms include n-propyl alcohol, isopropyl alcohol, 1-butyl alcohol, 2-butyl alcohol, isobutyl alcohol, tert-butyl alcohol, 1-pentanol, 2-pentanol, 3-pentanol, tert-pentyl alcohol, neopentyl alcohol, 2-methyl-1-butanol, 3-methyl-1-butanol, 3-methyl-3-pentanol, cyclopentanol, 1-hexanol, 2-hexanol, 3-hexanol, 2,3-dimethyl-2-butanol, 3,3-dimethyl-1-butanol, 3,3-dimethyl-2-butanol, 2-ethyl-1-butanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 4-methyl-3-pentanol, cyclohexanol, and 1-octanol.

Specific examples of the ether compounds having 8 to 12 carbon atoms include di-n-butyl ether, diisobutyl ether, di-sec-butyl ether, di-n-pentyl ether, diisopentyl ether, di-sec-pentyl ether, di-tert-pentyl ether, and di-n-hexyl ether.

Specific examples of the alkanes having 6 to 12 carbon atoms include hexane, heptane, octane, nonane, decane, undecane, dodecane, methylcyclopentane, dimethylcyclopentane, cyclohexane, methylcyclohexane, dimethylcyclohexane, cycloheptane, cyclooctane, and cyclononane. Specific examples of the alkenes having 6 to 12 carbon atoms include hexene, heptene, octene, cyclohexene, methylcyclohexene, dimethylcyclohexene, cycloheptene, and cyclooctene. Specific examples of the alkynes having 6 to 12 carbon atoms include hexyne, heptine, and octyne.

Specific examples of aromatic solvents include toluene, xylene, ethylbenzene, isopropylbenzene, tert-butylbenzene, and mesitylene.

Rinsing can reduce the risk of resist pattern collapse and defects. In addition, rinsing is not always necessary, and eliminating rinsing can reduce the amount of solvent used.

Dry development can also be used as a development method in the patterning process of the present invention. Dry development is a development method in which either the exposed or unexposed portions are removed by a gas etching process without using a developer. Dry etching can be performed using, for example, a known dry etching device. The etching gas used for dry etching can be appropriately selected depending on the mask pattern, the elemental composition of the film to be etched, and the like, and examples of the etching gas include fluorine-based gases such as CHF₃, CF₄, C₂F₆, C₃F₈, and SF₆; chlorine-based gases such as Cl₂ and BCl₃; oxygen-based gases such as O₂, O₃, and H₂O; reducing gases such as H₂, NH₃, CO, CO₂, CH₄, C₂H₂, C₂H₄, C₂H₆, C₃H₄, C₃H₆, C₃H₈, HF, HI, HBr, HCl, NO, NH₃, and BCl₃; and inert gases such as He, N₂, and Ar. These gases can also be used in combination.

### EXAMPLE

The present invention will be described in detail below regarding Examples and Comparative Examples, but the present invention is not limited to these Examples.

The silsesquioxane compounds and silsesquioxane precursors used in the Examples are listed below. The compound represented by the following formula (S-1) was used as the silsesquioxane precursor represented by the formulae (0c) and (6). The compounds represented by the formulae (S-2) to (S-3) were used as the fully caged silsesquioxane compound represented by the formula (1). The compound represented by the formula (S-4) was used as the partially caged silsesquioxane compound represented by the formula (2). The compound represented by the formula (S-5) was used as the ladder-type silsesquioxane compound having a repeating unit represented by the formula (3). The resin represented by the formula (S-6) was used as the silsesquioxane resin having a repeating unit represented by the formula (4a) or (4b). The polymer represented by the formula (S-7) was used as the polymer having a repeating unit represented by the formula (5).

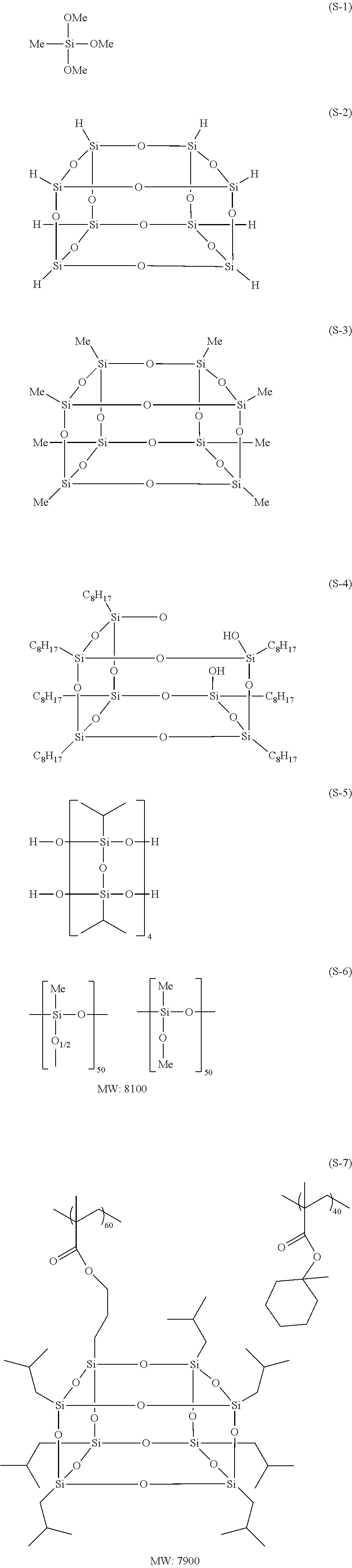

### [1] Preparation of Resist Composition

### Examples 1-1 to 1-12 and Comparative Example 1-1

Resist compositions R-1 to R-12 used in the present invention and comparative resist composition CR-1 were prepared by dissolving each component in a solvent according to the composition shown in Table 1 below and filtering the resulting solution through a 0.2 μm Teflon (registered trademark) filter.

TABLE 1

| | | Compo- | Compo- | |
|---|---|---|---|---|
| | Resist | nent A | nent B | Solvent |
| | compo- | (parts | (parts | (parts |
| | sition | by mass) | by mass) | by mass) |
| Example 1-1 | R-1 | S-1 (20.0) | — | PGMEA (1000) |
| Example 1-2 | R-2 | S-1 (20.0) | O-1 (1) | PGMEA (1000) |
| Example 1-3 | R-3 | S-2 (20.0) | — | PGMEA (1000) |
| Example 1-4 | R-4 | S-3 (20.0) | — | PGMEA (1000) |
| Example 1-5 | R-5 | S-3 (20.0) | P-1 (1) | PGMEA (1000) |
| Example 1-6 | R-6 | S-3 (20.0) | Sc-1 (1) | PGMEA (1000) |
| Example 1-7 | R-7 | S-3 (20.0) | Q-1 (1) | PGMEA (1000) |
| Example 1-8 | R-8 | S-3 (20.0) | X-1 (1) | PGMEA (1000) |
| Example 1-9 | R-9 | S-4 (20.0) | — | PGMEA (1000) |
| Example 1-10 | R-10 | S-5 (20.0) | — | PGMEA (1000) |
| Example 1-11 | R-11 | S-6 (20.0) | — | PGMEA (1000) |
| Example 1-12 | R-12 | S-7 (20.0) | P-1 (1) | PGMEA (1000) |
| Comparative | CR-1 | CM-1 (20.0) | — | PGMEA (1000) |
| Example 1-1 | | | | |

In Table 1, the component A is a silsesquioxane compound or silsesquioxane precursor, and the component B is other additives. The structures of the compounds (S-1) to (S-7) used as the component A are as described above. Details of the component B are as follows.
O-1: water
P-1: triphenylsulfonium tosylate
Sc-1: dibutylhydroxytoluene
Q-1: triphenylsulfonium acetate
X-1: tris(2,3-epoxypropyl)isocyanurate

In Table 1, PGMEA is propylene glycol monomethyl ether acetate.

In Table 1, CM-1 (tin compound) used in the Comparative Examples was synthesized according to Angewandte Chemie, International Edition (2017), 56(34), 10140-10144. The structure of CM-1 is as follows:

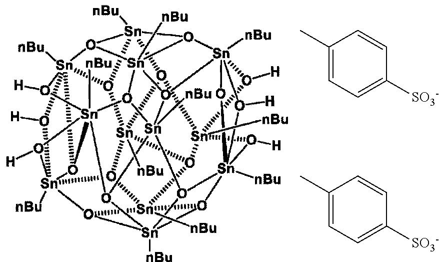

### [2] EUV and BEUV Lithography Evaluation

### Examples 2-1 to 2-14 and Comparative Example 2-1

Each resist composition (R-1 to R-12, CR-1) was spin-coated onto a Si substrate coated with a 60 nm thick anti-reflective coating DUV-42 (manufactured by Nissan Chemical Corporation). The substrate was then pre-baked at 100° C. for 60 seconds using a hot plate to produce a 40 nm thick resist film (Examples 2-1 to 2-12). In addition, the Si substrate coated with a 60 nm thick anti-reflective coating DUV-42 (manufactured by Nissan Chemical Corporation) was placed in a CVD device or ALD device and evacuated, a 40 nm thick silsesquioxane-containing resist film was fabricated using a silsesquioxane precursor (S-1) (Examples 2-13 to 2-14).

These resist films were subjected to two-beam interference exposure with 13.5 nm or 6.7 nm synchrotron radiation using New SUBARU (BL09), followed by PEB on a hot plate at 150° C. for 60 seconds, and then developed for 30 seconds using the developer or dry developer listed in Table 2 to form a pattern. As a result, a line-and-space (LS) pattern with a space width of 15 nm and a pitch of 30 nm was obtained. The resulting LS patterns were evaluated for sensitivity, LWR, and limiting resolution according to the methods described below. The results are shown in Table 2.

### [Sensitivity Evaluation]

The LS pattern was observed using an electron microscope to determine the optimal exposure dose Eop (μA·s) at which an LS pattern is obtained with a space width of 20 nm and a pitch of 40 nm, and this was used as the sensitivity.

### [LWR Evaluation]

The dimension of the LS pattern obtained by irradiation at the optimal exposure dose was measured at 10 locations along the longitudinal direction of the space width using a SEM (SU8600) manufactured by Hitachi High-Tech Corporation, and from the results, three times the standard deviation (σ) (3σ) was calculated, and this was used as the LWR. The smaller this value, the less roughness and the more uniform space width the pattern has.

### [Limiting Resolution Evaluation]

The limiting line width (nm) that was resolved when a pattern was formed by gradually increasing the exposure dose from the optimal exposure dose was determined using a critical dimension SEM (SU8600) manufactured by Hitachi High-Technologies Corporation, and this was taken as the limiting resolution (nm). This value is smaller, indicating the pattern having the better limiting resolution and the finer pattern can be formed.

TABLE 2

| | | | | | EUV (13.5 nm) | | | BEUV (6.7 nm) | | |
|---|---|---|---|---|---|---|---|---|---|---|
| | Resist | | | Negative | | | Limiting | | | Limiting |
| | com- | Film | | or | Eop | LWR | resolution | Eop | LWR | resolution |
| | position | formation | Development | positive | (mA · s) | (nm) | (nm) | (mA · s) | (nm) | (nm) |
| Example 2-1 | R-1 | Application | PGMEA | Negative | 60 | 5.7 | 14.5 | 20 | 3.1 | 6.0 |
| Example 2-2 | R-2 | Application | PGMEA | Negative | 57 | 5.9 | 14.8 | 17 | 3.1 | 6.2 |
| Example 2-3 | R-3 | Application | PGMEA | Negative | 55 | 5.9 | 14.6 | 15 | 3.2 | 6.5 |
| Example 2-4 | R-4 | Application | PGMEA | Negative | 53 | 5.5 | 14.4 | 12 | 2.8 | 6.0 |
| Example 2-5 | R-5 | Application | PGMEA | Negative | 51 | 5.7 | 14.7 | 11 | 3.0 | 5.8 |
| Example 2-6 | R-6 | Application | PGMEA | Negative | 64 | 5.4 | 14.7 | 14 | 3.1 | 5.9 |
| Example 2-7 | R-7 | Application | PGMEA | Negative | 67 | 5.3 | 14.5 | 17 | 2.7 | 6.0 |
| Example 2-8 | R-8 | Application | PGMEA | Negative | 50 | 5.9 | 14.9 | 12 | 2.9 | 5.7 |
| Example 2-9 | R-9 | Application | PGMEA | Negative | 58 | 5.8 | 14.4 | 17 | 3.0 | 6.2 |
| Example 2-10 | R-10 | Application | PGMEA | Negative | 59 | 6.1 | 14.2 | 19 | 3.1 | 6.1 |
| Example 2-11 | R-11 | Application | PGMEA | Negative | 62 | 6.1 | 15.0 | 12 | 3.1 | 5.9 |
| Example 2-12 | R-12 | Application | TMAH | Positive | 60 | 5.5 | 13.9 | 11 | 3.4 | 6.1 |
| Example 2-13 | — | CVD | CF4 | Negative | 55 | 5.2 | 14.0 | 10 | 2.5 | 5.0 |
| | | | dry | | | | | | | |
| | | | development | | | | | | | |
| Example 2-14 | — | ALD | CF4 | Negative | 54 | 5.2 | 14.0 | 10 | 2.5 | 4.9 |
| | | | dry | | | | | | | |
| | | | development | | | | | | | |
| Comparative | CR-1 | Application | PGMEA | Negative | 40 | 4.7 | 12.0 | 120 | 7.2 | 15.1 |
| Example 2-1 | | | | | | | | | | |

In Table 2, TMAH is a 2.38% aqueous solution of tetramethylammonium hydroxide.

The results shown in Table 2 demonstrate that the patterning process of the present invention, in which the resist film contains a silsesquioxane compound, is superior in sensitivity, LWR, and limiting resolution when the pattern is formed using BEUV.

Note that the present invention is not limited to the above-described embodiments. The above-described embodiments are merely illustrative, and any configuration that is substantially identical to the technical concept described in the claims of the present invention and that exhibits similar effects is within the technical scope of the present invention.

1. A patterning process comprising the steps of:
(1) forming a resist film on a substrate or on an underlayer film stacked on a substrate;
(2) exposing the resist film to BEUV light having a wavelength of 2 to 10 nm; and
(3) developing the exposed resist film to form a resist pattern,
wherein the resist film contains a silsesquioxane compound.

2. The patterning process according to claim 1, wherein in the step (1), the resist film is formed by CVD or ALD.

3. The patterning process according to claim 1, wherein in the step (1), the resist film is formed by applying a resist composition.

4. The patterning process according to claim 3, wherein the resist composition includes a fully caged silsesquioxane compound represented by the following formula (1): 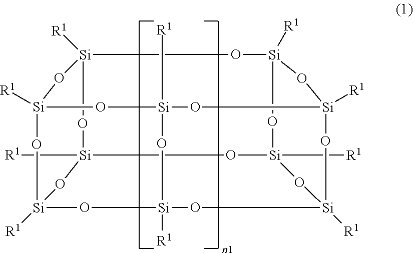
wherein “n1” is an integer of 0 to 40, R¹ is a hydrogen atom, a hydrocarbyl carbonyl group having 1 to 40 carbon atoms and optionally including a heteroatom, or a hydrocarbyl group having 1 to 40 carbon atoms and optionally including a heteroatom, and each R¹ is the same as or different from each other.

5. The patterning process according to claim 3, wherein the resist composition includes a partially caged silsesquioxane compound represented by the following formula (2): 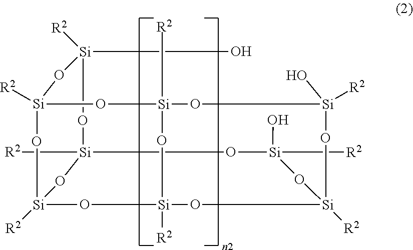
wherein “n2” is an integer of 0 to 40, R² is a hydrogen atom, a hydrocarbyl carbonyl group having 1 to 40 carbon atoms and optionally including a heteroatom, or a hydrocarbyl group having 1 to 40 carbon atoms and optionally including a heteroatom, and each R² is the same as or different from each other.

6. The patterning process according to claim 3, wherein the resist composition includes a ladder-type silsesquioxane compound represented by the following formula (3): 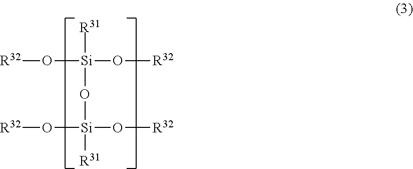
wherein R³¹ is a hydrogen atom, a hydrocarbyl carbonyl group having 1 to 40 carbon atoms and optionally including a heteroatom, or a hydrocarbyl group having 1 to 40 carbon atoms and optionally including a heteroatom, each R³¹ is the same as or different from each other, R³² is a hydrogen atom, a hydrocarbyl carbonyl group having 1 to 40 carbon atoms and optionally including a heteroatom, or a hydrocarbyl group having 1 to 40 carbon atoms and optionally including a heteroatom, each R³² is the same as or different from each other, and [ ] indicates a repeating unit.

7. The patterning process according to claim 3, wherein the resist composition includes a silsesquioxane resin having a repeating unit represented by the following formula (4a) or (4b): 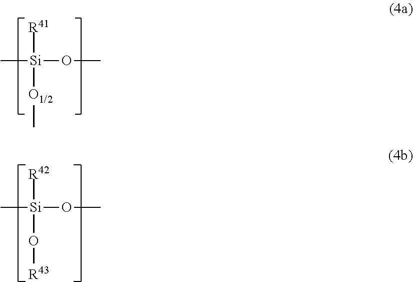
wherein R⁴¹, R⁴², and R⁴³ are each independently a hydrogen atom, a hydrocarbyl carbonyl group having 1 to 40 carbon atoms and optionally including a heteroatom, or a hydrocarbyl group having 1 to 40 carbon atoms and optionally including a heteroatom.

8. The patterning process according to claim 3, wherein the resist composition includes a polymer having a repeating unit represented by the following formula (5): 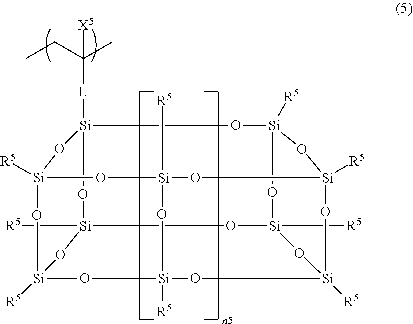
wherein “n5” is an integer of 0 to 40, R⁵ is a hydrogen atom, a hydrocarbyl carbonyl group having 1 to 40 carbon atoms and optionally including a heteroatom, or a hydrocarbyl group having 1 to 40 carbon atoms and optionally including a heteroatom, each R⁵ is the same as or different from each other, L is a single bond or a divalent linking group, X⁵ is a hydrogen atom, a halogen atom, a methyl group, or a trifluoromethyl group, and ( ) indicates a repeating unit.

9. The patterning process according to claim 3, wherein the resist composition includes a silsesquioxane precursor represented by the following formula (6):
R⁶¹—Si(X⁶)₃ (6)
wherein R⁶¹ is a hydrogen atom, a hydrocarbyl carbonyl group having 1 to 40 carbon atoms and optionally including a heteroatom, or a hydrocarbyl group having 1 to 40 carbon atoms and optionally including a heteroatom, each R⁶¹ is the same as or different from each other, X⁶ is a hydrogen atom, a halogen atom, or a monovalent organic group represented by —O—R⁶², R⁶² is a hydrogen atom, a hydrocarbyl carbonyl group having 1 to 40 carbon atoms and optionally including a heteroatom, or a hydrocarbyl group having 1 to 40 carbon atoms and optionally including a heteroatom, and each X⁶ is the same as or different from each other.

10. The patterning process according to claim 1, wherein in the step (3), the development is dry development.

11. The patterning process according to claim 2, wherein in the step (3), the development is dry development.

12. The patterning process according to claim 3, wherein in the step (3), the development is dry development.

13. The patterning process according to claim 4, wherein in the step (3), the development is dry development.

14. The patterning process according to claim 5, wherein in the step (3), the development is dry development.

15. The patterning process according to claim 6, wherein in the step (3), the development is dry development.

16. The patterning process according to claim 7, wherein in the step (3), the development is dry development.

17. The patterning process according to claim 8, wherein in the step (3), the development is dry development.

18. The patterning process according to claim 9, wherein in the step (3), the development is dry development.
